(19) United States
(12) Patent Application Publication
(10) Pub. No.: US 2023/0395753 A1
(43) Pub. Date: Dec. 7, 2023

(54) DISPLAY DEVICE

(71) Applicant: Samsung Display Co., LTD., Yongin-si (KR)

(72) Inventors: Yong Sik HWANG, Yongin-si (KR); Seung Kyu LEE, Yongin-si (KR)

(73) Assignee: Samsung Display Co., LTD., Yongin-si (KR)

(21) Appl. No.: 18/304,530

(22) Filed: Apr. 21, 2023

(30) Foreign Application Priority Data
Jun. 3, 2022 (KR) 10-2022-0068163

(51) Int. Cl. H01L 33/38; H01L 33/62; H01L 33/50; H01L 25/075

(52) U.S. Cl. CPC H01L 33/38; H01L 33/62; H01L 33/502; H01L 25/0753

(57) ABSTRACT

A display device includes a bank layer defining an emission area in which light-emitting elements are disposed, a first electrode and a second electrode that are spaced apart from each other in the emission area, the light-emitting elements being disposed between the first electrode and the second electrode, and an electrode pattern layer disposed above the bank layer, the light-emitting elements, the first electrode and the second electrode. The electrode pattern layer includes a lattice pattern that does not overlap the emission area and that surrounds edges of the emission area, and a slit pattern overlapping the emission area.

### CROSS-REFERENCE TO RELATED APPLICATION(S)

This application claims priority to and benefits of Korean Patent Application No. 10-2022-0068163 under 35 U.S.C. § 119, filed on Jun. 3, 2022 in the Korean Intellectual Property Office (KIPO), the entire contents of which are incorporated herein by reference.

### BACKGROUND

### 1. Field of the Disclosure

The disclosure relates to a display device.

### 2. Description of the Related Art

Display devices become more and more important as multimedia technology evolves. Accordingly, a variety of types of display devices such as organic light-emitting display (OLED) devices and liquid-crystal display (LCD) devices are currently used.

Display devices include a display panel such as an organic light-emitting display panel or a liquid-crystal display panel for displaying images. Among display panels, light-emitting display panels may include light-emitting elements. For example, light-emitting diodes (LEDs) may include an organic light-emitting diode (OLED) using an organic material as a fluorescent material, and an inorganic light-emitting diode using an inorganic material as a fluorescent material.

An inorganic light-emitting diode using an inorganic semiconductor as the fluorescent material has advantages such as durability in high-temperature environments and higher efficiency of blue light relative to organic light-emitting diodes.

### SUMMARY

Aspects of the disclosure provide a display device with improved light-emitting efficiency of pixels.

Aspects of the disclosure also provide a display device that can prevent damage to elements due to static electricity.

It should be noted that aspects of the disclosure are not limited to those mentioned above; and other aspects of the disclosure will be apparent to those skilled in the art from the following descriptions.

According to an embodiment of the disclosure, a display device may include a bank layer defining an emission area in which light-emitting elements are disposed, a first electrode and a second electrode that are spaced apart from each other in the emission area, the light-emitting elements being disposed between the first electrode and the second electrode, and an electrode pattern layer disposed above the bank layer, the light-emitting elements, the first electrode and the second electrode. The electrode pattern layer may include a lattice pattern that does not overlap the emission area and that surrounds edges of the emission area, and a slit pattern overlapping the emission area.

In an embodiment, the lattice pattern may overlap the bank layer, and the slit pattern may not overlap the bank layer.

In an embodiment, a first supply voltage may be applied to the first electrode, a second supply voltage having a lower level than a level of the first supply voltage may be applied to the second electrode, and the electrode pattern layer may further include a contact electrically connected to the second electrode.

In an embodiment, the second electrode may be in direct contact with the contact of the electrode pattern layer.

In an embodiment, the slit pattern may include a plurality of scattering members spaced apart from one another with slits extended to traverse the emission area therebetween, and at least one of the plurality of scattering members may overlap the light-emitting elements.

In an embodiment, the display device may further include a capping layer disposed between the light-emitting elements and the plurality of scattering members, and a wavelength conversion material disposed on an upper surface of the plurality of scattering members to convert a wavelength of light output from the light-emitting elements.

In an embodiment, the scattering members and the lattice pattern may include a same material.

In an embodiment, the scattering members may include a transparent conductive oxide.

In an embodiment, the slits may be extended in a direction parallel to an extending direction of the light-emitting elements.

In an embodiment, the slits may be extended in a direction intersecting an extending direction of the light-emitting elements.

According to an embodiment of the disclosure, a display device may include a first electrode disposed on a substrate to receive a first supply voltage, a second electrode spaced apart from the first electrode on the substrate to receive a second supply voltage having a level lower than a level of the first supply voltage, light-emitting elements disposed on a space between the first electrode and the second electrode, a capping layer disposed above the first electrode, the second electrode, and the light-emitting elements, and a ground electrode disposed on the capping layer. The ground electrode may be electrically connected to the second electrode.

In an embodiment, the display device may further include a second supply voltage line disposed between the substrate and the second electrode and applying the second supply voltage to the second electrode, and a driver disposed on the substrate to apply a driving signal to the light-emitting elements. The second supply voltage line and the driver may be electrically connected with each other.

In an embodiment, the display device may further include a via insulating layer disposed between the second supply voltage line and the second electrode. The second electrode may be in electrical contact with the second supply voltage line through an electrode contact hole penetrating the via insulating layer.

In an embodiment, the electrode contact hole may pass through the capping layer, and the ground electrode may be in direct contact with the second electrode through the electrode contact hole.

In an embodiment, the ground electrode may not overlap the light-emitting elements.

In an embodiment, the display device may further include a plurality of scattering members spaced apart from one another, at least one of the scattering members overlapping the light-emitting elements. The ground electrode and the plurality of scattering members may include a same material.

In an embodiment, the ground electrode may include a transparent conductive oxide.

According to an embodiment, a display device may include a bank layer disposed on a substrate to define an emission area in which light-emitting elements are disposed, a first electrode and a second electrode that are disposed on the substrate and spaced apart from each other in the emission area, the light-emitting elements disposed between the first electrode and the second electrode, a capping layer disposed above the bank layer, the first electrode, the second electrode, and the light-emitting elements, and a plurality of scattering members disposed on the capping layer such that the plurality of scattering members are spaced apart from one another. At least one scattering member among the plurality of scattering members may overlap the light-emitting elements.

In an embodiment, the plurality of scattering members may not overlap the bank layer.

In an embodiment, the plurality of scattering members may include a transparent conductive oxide.

According to an embodiment of the disclosure, the light-emitting efficiency of pixels in a display device can be improved.

According to an embodiment of the disclosure, it may be possible to prevent damage to elements in a display device due to static electricity.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a plan view schematically showing a display device according to an embodiment of the disclosure.

FIG. 2 is a plan view schematically showing a film member, a display panel and a chassis member included in a display device according to an embodiment.

FIG. 3 is a cross-sectional view schematically showing a cross section taken along line X1-X1′ of FIG. 2.

FIG. 4 is a circuit diagram schematically showing a pixel of a display device according to an embodiment of the disclosure.

FIG. 5 is a plan view schematically showing light-emitting elements, alignment electrodes and connection electrodes of a display device according to an embodiment of the disclosure.

FIG. 6 is a view schematically showing the structure of a light-emitting element of a display device according to an embodiment of the disclosure.

FIG. 7 is a plan view schematically showing an electrode pattern layer of a display device according to an embodiment of the disclosure.

FIG. 8 is a plan view schematically showing wavelength control areas of the display device according to an embodiment of the disclosure.

FIG. 9 is a cross-sectional view schematically showing a cross-section taken along line X2-X2′ of FIGS. 5, 6 and 8.

FIG. 10 is a cross-sectional view schematically showing a cross-section taken along line X3-X3′ of FIGS. 5 and 8.

FIG. 11 is a cross-sectional view schematically showing a cross-section taken along line X4-X4′ of FIGS. 5 and 8.

FIGS. 12 and 13 are views schematically illustrating paths via which static electricity is discharged through the electrode pattern layer of the display device according to an embodiment.

FIG. 14 is a plan view schematically showing an electrode pattern layer of a display device according to another embodiment of the disclosure.

FIG. 15 is a plan view schematically showing an electrode pattern layer of a display device according to yet another embodiment of the disclosure.

FIG. 16 is a plan view schematically showing light-emitting elements, alignment electrodes and connection electrodes of a display device according to still another embodiment of the disclosure.

FIG. 17 is a plan view schematically showing an electrode pattern layer of the display device according to an embodiment of FIG. 16.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Features of each of various embodiments of the disclosure may be partially or entirely combined with each other and may technically variously interwork with each other, and respective embodiments may be implemented independently of each other or may be implemented together in association with each other.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

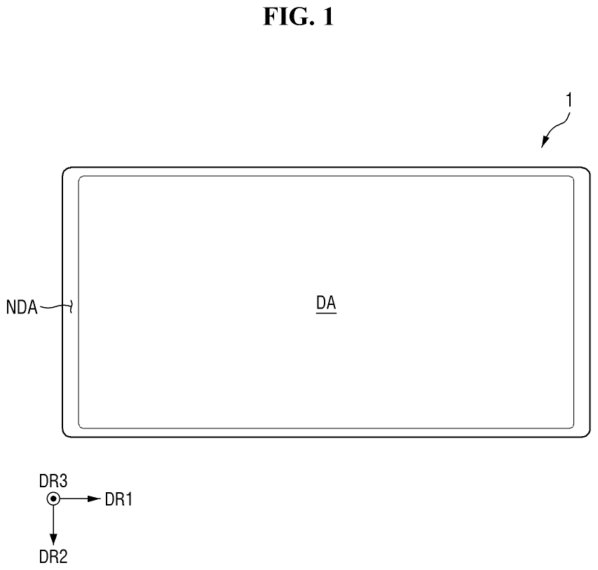

FIG. 1 is a plan view schematically showing a display device according to an embodiment of the disclosure.

In FIG. 1, a first direction DR1, a second direction DR2 and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. The first direction DR1 may refer to the horizontal direction in the drawings, the second direction DR2 may refer to the vertical direction in the drawings, and the third direction DR3 may refer to an up-and-down direction, i.e., a thickness direction in the drawings. As used herein, a direction may refer to the direction indicated by the arrow as well as the opposite direction, unless specifically stated otherwise. If it is necessary to discern between such two opposite directions, one of the two directions may be referred to as “one side in the direction,” while the other direction may be referred to as “the opposite side in the direction”. In FIG. 1, the side indicated by the arrow of a direction is referred to as one side in the direction, while the opposite side is referred to as the opposite side in the direction.

In the following description of the surfaces of the display device 1 or the elements of the display device 1, the surfaces facing one side where images may be displayed, i.e., the third direction DR3 will be referred to as the upper surface, while the opposite surfaces will be referred to as the lower surface for convenience of illustration. It should be understood, however, that the disclosure is not limited thereto. The surfaces and the opposite surface of the elements may be referred to as a front surface and a rear surface, respectively, or may be referred to as a first surface and a second surface, respectively. In addition, in the description of relative positions of the elements of the display device 1, one side in the second direction DR2 may be referred to as the upper side while the opposite side in the second direction DR2 may be referred to as the lower side.

Referring to FIG. 1, a display device 1 may display a moving image or a still image. A display device 1 may refer to any electronic device that provides a display screen. For example, the display device 1 may include a television set, a laptop computer, a monitor, an electronic billboard, Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console, a digital camera, a camcorder, etc.

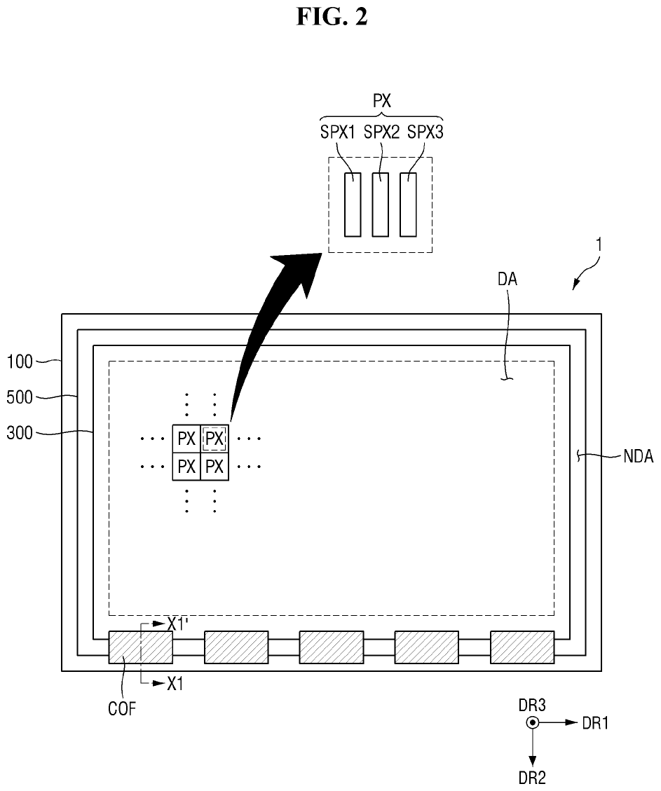

The display device 1 may include a display panel 300 for providing a display screen (see FIG. 2). Examples of the display panel 300 may include an inorganic light-emitting diode display panel, an organic light-emitting display panel, a quantum-dot light-emitting display panel, a plasma display panel, a field emission display panel, etc. In the following description, an inorganic light-emitting diode display panel is employed as an example of the display panel 300, but the disclosure is not limited thereto. Any other display panel may be employed as long as the technical idea of the disclosure may be applied.

The shape of the display device 1 may be modified in a variety of ways. For example, the display device 1 may have shapes such as a rectangle with longer lateral sides, a rectangle with longer vertical sides, a square, a quadrangle with rounded corners (vertices), other polygons, a circle, etc. The shape of a display area DA of the display device 1 may also be similar to the overall shape of the display device 1. In the example shown in FIG. 1, the display device 1 has a rectangular shape with the longer sides in the first direction DR1.

The display device 1 may include the display area DA and a non-display area NDA. In the display area DA, images can be displayed. In the non-display area NDA, images may not be displayed. The display area DA may be referred to as an active area, while the non-display area NDA may be referred to as an inactive area. The display area DA may generally occupy the center of the display device 1. It should be understood, however, that the disclosure is not limited thereto.

The non-display area NDA may be disposed around the display area DA. In other words, the non-display area NDA may surround the edge of the display area DA. In some embodiments, the display area DA may have a rectangular shape, and the non-display areas NDA may be disposed to be adjacent to the four sides of the display area DA. It should be understood, however, that the disclosure is not limited thereto. The non-display area NDA may form the bezel of the display device 1. Lines or circuit drivers included in the display device 1 may be disposed in each of the non-display area NDA, or external devices may be mounted.

The display area DA and the non-display area NDA of the display device 1 may also be applied to the elements included in the display device 1. Hereinafter, the elements included in the display device 1 will be described.

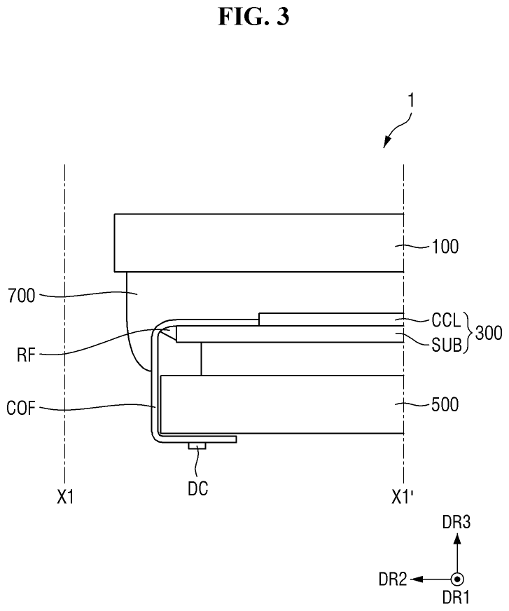

FIG. 2 is a plan view schematically showing a film member, a display panel and a chassis member included in a display device according to an embodiment. FIG. 3 is a cross-sectional view schematically showing a cross section taken along line X1-X1′ of FIG. 2.

Referring to FIGS. 2 and 3, the display device 1 may include a film member 100, a display panel 300, and a chassis member 500. The display device 1 may be configured by stacking the chassis member 500, the display panel 300 and the film member 100 on each other in this order in the third direction DR3. For convenience of illustration, the film member 100, the display panel 300 and the chassis member 500 will be described in this order.

The film member 100 can protect the display device 1 from the outside. The film member 100 may be disposed at the top of the display device 1 to protect the display panel 300 disposed under the film member 100. In other words, the film member 100 may be attached to the upper surface of the display panel 300 by a sealing member 700 disposed between the film member 100 and the display panel 300.

The area of the film member 100 may be greater than the area of the display panel 300, and may be greater than the area of the chassis member 500. In other words, the film member 100 may completely cover the display panel 300 and the chassis member 500 and may be extended beyond the display panel 300 and the chassis member 500. The structure of the film member 100 will be described later.

The display panel 300 can display images thereon. The display panel 300 may define the display area DA of the display device 1. The display area DA of the display panel 300 may include pixels PX. The pixels PX may be arranged in a matrix. The shape of each of the pixels PX may be, but is not limited to being, rectangular or square in plan view. For example, the shape of each of the pixels PX may have a diamond shape having the sides inclined with respect to a direction.

Each of the pixels PX may include multiple emission areas, each of which emits light of a particular wavelength band. For example, a pixel PX may include a first sub-pixel SPX1, a second sub-pixel SPX2 and a third sub-pixel SPX3. Although the single pixel PX includes three sub-pixels SPXn in the example shown in FIG. 2, the disclosure is not limited thereto. For example, a pixel PX may include more than three sub-pixels SPXn.

The first sub-pixel SPX1 may emit light of a first color, the second sub-pixel SPX2 may emit light of a second color, and the third sub-pixel SPX3 may emit light of a third color. For example, the light of the first color may be red light having a peak wavelength in the range of 610 to 650 nm, the light of the second color may be green light having a peak wavelength in the range of 510 to 550 nm, and the light of the third color may be blue light having a peak wavelength in the range of 440 to 480 nm. It is, however, to be understood that the disclosure is not limited thereto.

The display panel 300 may include a substrate SUB and a circuit element layer CCL disposed on the substrate SUB. The structure of the display panel 300 will be described in detail later.

The chassis member 500 can support the bottom of the display panel 300 to improve mechanical strength. The chassis member 500 may be disposed on the bottom of the display panel 300. The chassis member 500 may include a material having rigidity to ensure mechanical strength, for example, a metal such as SUS304 and aluminum.

A flexible printed circuit board COF may be disposed on a side of the display panel 300 to supply a driving signal to the pixels PX of the display panel 300. More than one flexible printed circuit board COF may be disposed such that they are spaced apart from each other. The flexible printed circuit board COF may be electrically connected to the pixels PX through the circuit element layer CCL of the display panel 300.

As used herein, when an element is referred to as being “connected” or “coupled” to another element, it can be directly connected or coupled to the element or intervening elements may be present. In addition, such elements may be understood as a single integrated element with one portion thereof connected to another portion. Moreover, when an element is referred to as being “connected” to another element, it may be in physical contact with the element and/or electrically connected to the element.

The flexible printed circuit board COF may be extended from a side of the display panel 300 to the chassis member 500 and may be attached to the bottom of the chassis member 500. For example, as shown in FIG. 3, the flexible printed circuit board COF may be disposed at the end of the substrate SUB of the display panel 300 and bent toward the chassis member 500 to be attached to the bottom of the chassis member.

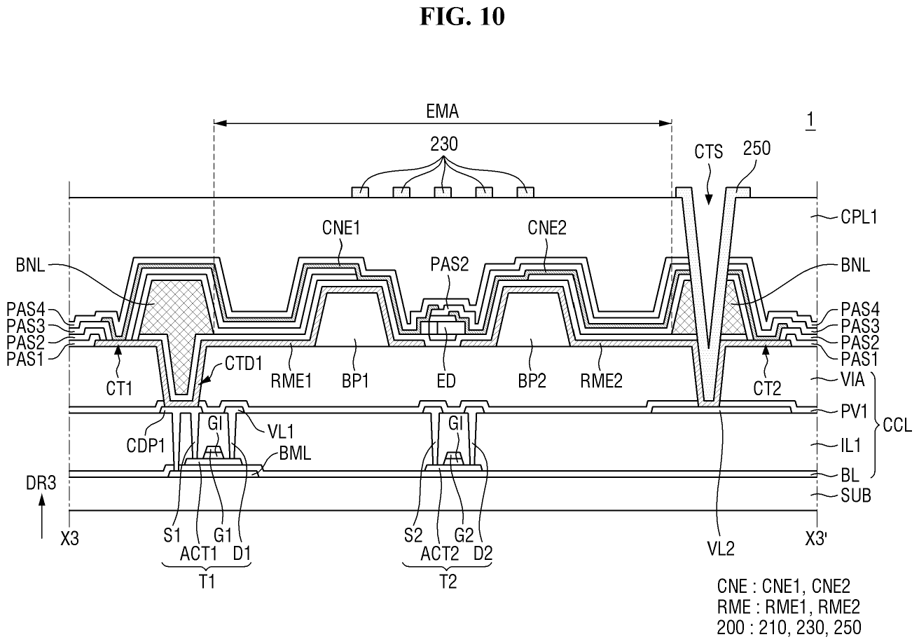

A driving chip DC generating a driving signal may be mounted on the flexible printed circuit board COF. For example, the driving chip DC may be electrically connected to a first voltage line VL1 (see FIG. 10) and a second voltage line VL2 (see FIG. 10) of the circuit element layer CCL. In some embodiments, the driving chip DC may be disposed on a surface of the flexible printed circuit board COF to face the outside of the display device 1, but the disclosure is not limited thereto.

A resin RF may be interposed between the flexible printed circuit board COF and the side surface of the substrate SUB of the display panel 300. The resin RF can make up the level difference between the display panel 300 and the chassis member 500 in the second direction DR2, so that it can mitigate stress which may be applied to the flexible printed circuit board COF by bending of the flexible printed circuit board COF.

Hereinafter, a pixel driving circuit of a pixel PX of a display device according to an embodiment will be described.

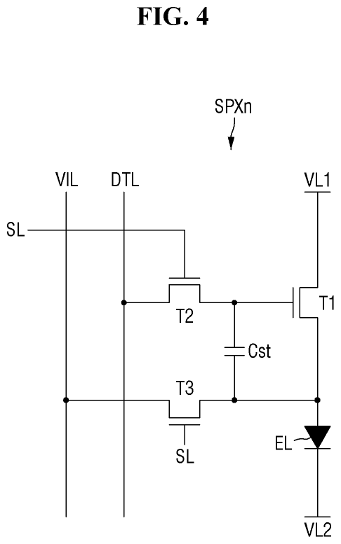

FIG. 4 is a circuit diagram schematically showing a pixel of a display device according to an embodiment of the disclosure.

Referring to FIG. 4, each of the pixels PX or sub-pixels SPXn of the display device 1 may include a pixel driving circuit, where n may be an integer of 1 to 3. The pixel driving circuit may include a transistor and a capacitor. The numbers of transistors and capacitors of each pixel driving circuit may be changed in a variety of ways. According to an embodiment of the disclosure, each of the sub-pixels SPXn of the display device 1 may have a 3T1C structure, i.e., a pixel driving circuit includes three transistors and a capacitor. In the following description, the pixel driving circuit having the 3T1C structure will be described as an example. It is, however, to be understood that the disclosure is not limited thereto. A variety of modified structures may be employed such as a 2T1C structure, a 7T1C structure or a 6T1C structure.

Each of the sub-pixels SPXn of the display device 1 according to an embodiment may include three transistors T1, T2 and T3 and a storage capacitor Cst in addition to a light-emitting diode EL.

The light-emitting diode EL may emit light proportional to the current supplied through the first transistor T1. The light-emitting diode EL may include a first electrode, a second electrode, and at least one light-emitting element disposed therebetween. The light-emitting element may emit light in a particular wavelength range by an electric signal transmitted from the first electrode and the second electrode.

A first end of the light-emitting diode EL may be connected to a source electrode of the first transistor T1, and a second end thereof may be connected to a second voltage line VL2 from which a low-level voltage (hereinafter referred to as a second supply voltage) lower than a high-level voltage (hereinafter referred to as a first supply voltage) of a first voltage line VL1 may be applied.

The first transistor T1 may adjust a current flowing from the first voltage line VL1 from which the first supply voltage is supplied to the light-emitting diode EL according to the voltage difference between a gate electrode and the source electrode. For example, the first transistor T1 may be a driving transistor for driving the light-emitting diode EL. The gate electrode of the first transistor T1 may be connected to a source electrode of the second transistor T2, the source electrode thereof may be connected to the first electrode of the light-emitting diode EL, and the drain electrode thereof may be connected to the first voltage line VL1 from which the first supply voltage is applied.

The second transistor T2 may be turned on by a scan signal of the scan line SL to connect the data line DTL to the gate electrode of the first transistor T1. The gate electrode of the second transistor T2 may be connected to the scan line SL, the source electrode thereof may be connected to the gate electrode of the first transistor T1, and the drain electrode thereof may be connected to the data line DTL.

The third transistor T3 may be turned on by a scan signal of the scan line SL to connect the initialization voltage line VIL to an end of the light-emitting diode EL. The gate electrode of the third transistor T3 may be connected to the scan line SL, the drain electrode thereof may be connected to the initialization voltage line VIL, and the source electrode thereof may be connected to an end of the light-emitting diode EL or the source electrode of the first transistor T1.

The source electrode and the drain electrode of each of the transistors T1, T2 and T3 are not limited to those described above. They may be connected in the opposite way. Each of the transistors T1, T2 and T3 may be formed as a thin-film transistor. Although each of the transistors T1, T2 and T3 are implemented as an n-type MOSFET (metal oxide semiconductor field effect transistor) in the example shown in FIG. 3, the disclosure is not limited thereto. For example, each of the transistors T1, T2 and T3 may be implemented as a p-type MOSFET, or some of the transistors T1, T2 and T3 may be implemented as n-type MOSFETs while others may be implemented as p-type MOSFETs.

The storage capacitor Cst may be formed between the gate electrode and the source electrode of the first transistor T1. The storage capacitor Cst may store a voltage difference between the gate voltage and the source voltage of the first transistor T1.

According to an embodiment of the disclosure, the gate electrode of the second transistor T2 may be connected to the scan line SL, and the gate electrode of the third transistor T3 may be connected to the scan line SL. In other words, the second transistor T2 and the third transistor T3 may be turned on by the scan signal applied from the same scan line. It should be understood, however, that the disclosure is not limited thereto. The second transistor T2 and the third transistor T3 may be connected to different scan lines and may be turned on in response to scan signals applied from the different scan lines.

Hereinafter, the structure of a pixel PX of the display device 1 according to an embodiment of the disclosure will be described.

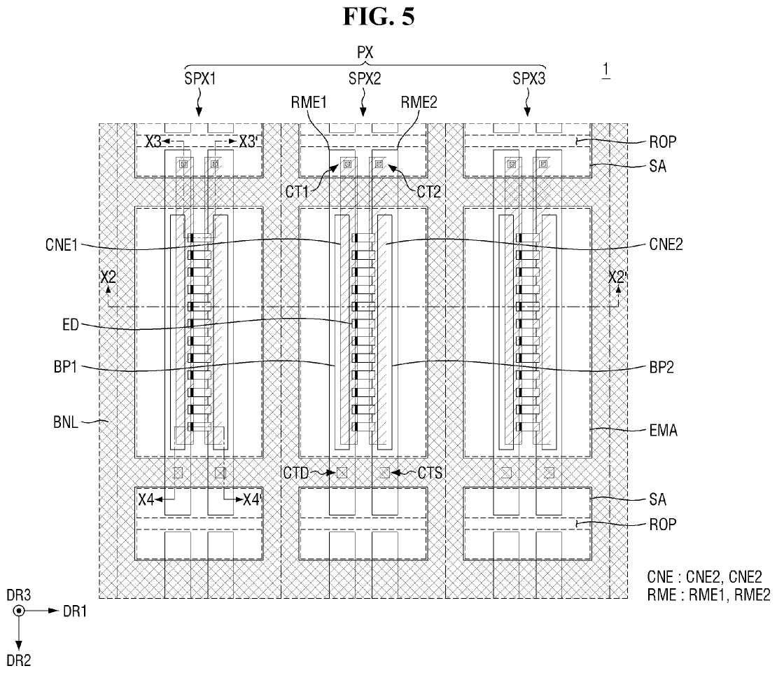

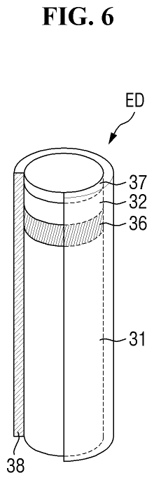

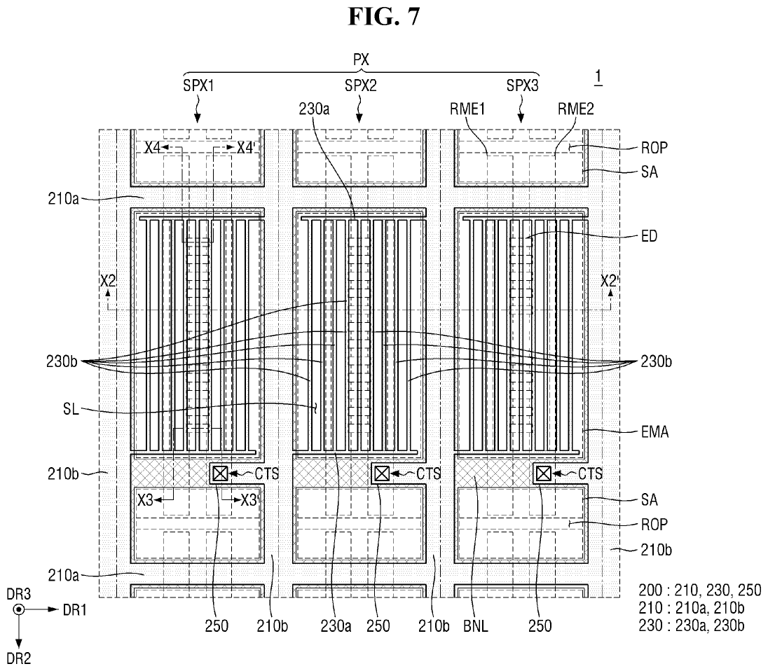

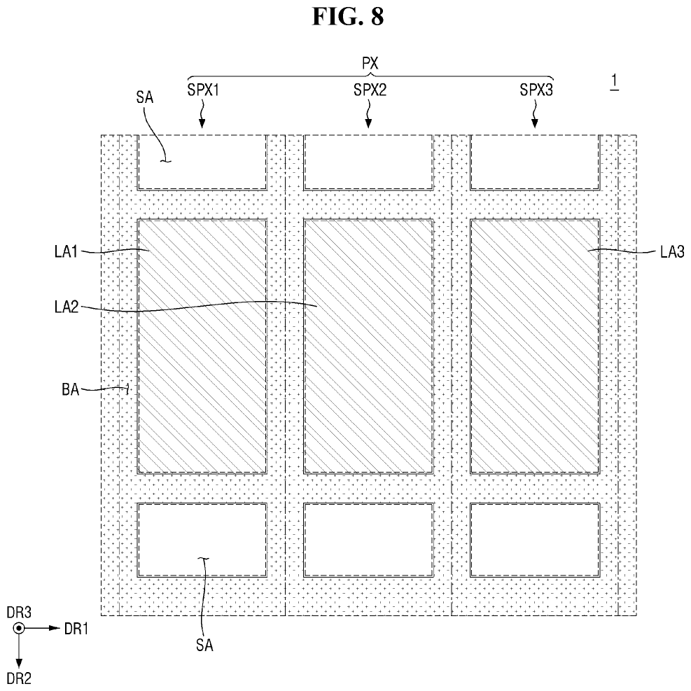

FIG. 5 is a plan view schematically showing light-emitting elements, alignment electrodes and connection electrodes of a display device according to an embodiment of the disclosure. FIG. 6 is a view schematically showing the structure of a light-emitting element of a display device according to an embodiment of the disclosure. FIG. 7 is a plan view schematically showing an electrode pattern layer of a display device according to an embodiment of the disclosure. FIG. 8 is a plan view schematically showing wavelength control areas of the display device according to an embodiment of the disclosure.

Although the emission area EMA or the wavelength control areas LA1, LA2 and LA3 of each sub-pixel SPXn have a uniform area in FIGS. 5 to 8, the disclosure is not limited thereto. In some embodiments, the emission areas EMA or the wavelength control areas LA1, LA2 and LA3 of each sub-pixel SPXn may have different areas.

Referring to FIGS. 5 to 7, each sub-pixel SPXn of the pixel PX of the display device 1 according to an embodiment may include an emission area EMA and a non-emission area. In the emission area EMA, light-emitting elements ED may be disposed to emit light of a particular wavelength band. In the non-emission area, the light-emitting elements ED may not be disposed and light emitted from the light-emitting diodes ED may not reach, and thus no light exits therefrom.

The emission area EMA of the sub-pixel SPXn may include an area in which the light-emitting elements ED are disposed, and may include an area adjacent to the light-emitting elements ED where light emitted from the light-emitting elements ED exit. For example, the emission area EMA may also include an area in which light emitted from the light-emitting elements ED are reflected or refracted by other elements to exit. The light-emitting elements ED may be disposed in the pixels PX, respectively, and the emission area EMA may include the area where the light-emitting elements are disposed and adjacent areas.

Each of the sub-pixels SPXn may further include a subsidiary area SA disposed in the non-emission area. The subsidiary area SA of each sub-pixel SPXn may be disposed on the sides of the emission area EMA in the second direction DR2. The emission areas EMA and the subsidiary areas SA may be arranged alternately in the second direction DR2, and each subsidiary area SA may be disposed between the emission areas EMA of different pixels PX spaced apart from each other in the second direction DR2. For example, the emission areas EMA and the subsidiary areas SA may be alternately arranged in the second direction DR2, and the emission areas EMA may be repeatedly arranged in the first direction DR1 and so may the subsidiary areas SA. It should be understood, however, that the disclosure is not limited thereto.

No light-emitting element ED may be disposed in the subsidiary areas SA and thus no light exits therefrom. The alignment electrodes RME disposed in the sub-pixels SPXn may be partially disposed in the subsidiary areas SA. The alignment electrodes RME disposed in different sub-pixels SPXn may be disposed separately from one another at separation regions ROP of the subsidiary areas SA.

The display device 1 may include alignment electrodes RME: RME1 and RME2, bank patterns BP1 and BP2, a bank layer BNL, light-emitting elements ED, and connection electrodes CNE: CNE1 and CNE2.

The bank layer BNL may be disposed in a lattice pattern on the entire surface of the display area DA including portions extended in the first direction DR1 and the second direction DR2 in plan view. For example, the bank layer BNL may surround each of the sub-pixels SPXn. The bank layer BNL may surround each of the sub-pixels SPXn, and may define the emission area EMA and the subsidiary area SA. The distance between the sub-pixels SPXn, the emission areas EMA and the subsidiary areas SA may vary depending on the width of the bank layer BNL.

The bank patterns BP1 and BP2 may be disposed in the emission area EMA of each sub-pixel SPX. Each of the bank patterns may have a shape that has a constant width in the first direction DR1 and is extended in the second direction DR2.

For example, the bank patterns may include a first bank pattern BP1 and a second bank pattern BP2 spaced apart from each other in the first direction DR1 in the emission area EMA of each of the sub-pixels SPXn. The first bank pattern BP1 may be disposed on the opposite side of the center of the emission area EMA in the first direction DR1, and the second bank pattern BP2 may be disposed on one side of the center of the emission area EMA in the first direction DR1. The first bank pattern BP1 and the second bank pattern BP2 may be alternately arranged along the first direction DR1 and may be disposed in an island-like pattern in the display area DA. The light-emitting elements ED may be disposed between the first bank pattern BP1 and the second bank pattern BP2 spaced apart from each other.

The width of the first bank pattern BP1 in the first direction DR1 may be equal to the width of the second bank pattern BP2 in the first direction DR1. It should be understood, however, that the disclosure is not limited thereto. The width of the first bank pattern BP1 in the second direction DR2 and the width of the second bank pattern BP2 in the second direction DR2 may be equal to each other, and the width of the emission area EMA surrounded by the bank layer BNL may be smaller than the width in the second direction DR2. In some embodiments, the first bank pattern BP1 and the second bank pattern BP2 may be spaced apart from the portions of the bank layer BNL that are extended in the first direction DR1. It should be understood, however, that the disclosure is not limited thereto.

The alignment electrodes RME: RME1 and RME2 may have a shape extended in a direction and may be disposed in each of the sub-pixels SPXn. The alignment electrodes RME may be extended in the second direction DR2 to be disposed in the emission area EMA and the subsidiary area SA of the sub-pixel SPXn, and they may be spaced apart from one another in the first direction DR1.

The alignment electrodes RME may include a first alignment electrode RME1 and a second alignment electrode RME2. The first alignment electrode RME1 may be disposed on the opposite side of the center of the emission area EMA in the first direction DR1, and the second alignment electrode RME2 may be disposed on one side of the center of the emission area EMA in the first direction DR1. The first alignment electrode RME1 may be disposed on the first bank pattern BP1, and the second alignment electrode RME2 may be disposed on the second bank pattern BP2. The first alignment electrode RME1 and the second alignment electrode RME2 may be extended beyond the bank layer BNL and may be partially disposed in the emission area EMA and the subsidiary area SA of the sub-pixel SPXn. The first alignment electrode RME1 and the second alignment electrode RME2 of a sub-pixel SPXn may be spaced apart from those of another sub-pixel SPXn at the separation region ROP located in the subsidiary area SA of a subpixel SPXn.

The first alignment electrode RME1 may be electrically connected to the circuit element layer CCL (see FIG. 10) through a first electrode contact hole CTD, and the second alignment electrode RME2 may be electrically connected to the circuit element layer CCL (see FIG. 10) through a second electrode contact hole CTS.

Although two electrodes RME are disposed in each of the sub-pixels SPXn and have a shape extended in the second direction DR2 in FIG. 5, the disclosure is not limited thereto. For example, more than two alignment electrodes RME may be disposed in a single sub-pixel SPXn of the display device 1, or the alignment electrodes RME may be partially bent and may have varying widths depending on position.

The light-emitting elements ED may be disposed in the emission area EMA. In other words, the light-emitting elements ED may be disposed in the space between the first bank pattern BP1 and the second bank pattern BP2 disposed in the emission area EMA of a sub-pixel SPXn, and may be arranged such that they are spaced apart from one another in the second direction DR2. According to an embodiment of the disclosure, the light-emitting elements ED may have a shape extended in a direction, and the ends of light-emitting elements ED may be disposed on different electrodes RME, respectively. The width of the light-emitting elements ED in the first direction DR1 may be greater than the width of the space between the first alignment electrode RME1 and the second alignment electrode RME2 in the first direction DR1. The light-emitting elements ED may be arranged such that the direction in which they are extended is generally perpendicular to the second direction DR2 in which the alignment electrodes RME are extended. It should be understood, however, that the disclosure is not limited thereto. For example, the light-emitting elements ED may be extended in the first direction DR1 or in a direction oblique to the first direction DR1.

A light-emitting element ED may be a light-emitting diode. Specifically, the light-emitting elements ED may have size from nanometers to micrometers and may be inorganic light-emitting diodes made of an inorganic material. The light-emitting element ED may be aligned between two electrodes facing each other as polarities are created by forming an electric field in a particular direction between the two electrodes.

The light-emitting element ED according to an embodiment may have a shape extended in a direction. In some embodiments, the light-emitting element ED may have, but is not limited to, a shape of a cylinder, a rod, a wire, a tube, etc.

The light-emitting element ED may include semiconductor layers doped with a dopant of a conductive type (e.g., p-type or n-type). The semiconductor layers may emit light of a certain wavelength band by transmitting an electric signal applied from an external power source.

As shown in FIG. 6, the light-emitting diode ED may include a first semiconductor layer 31, a second semiconductor layer 32, an emissive layer 36, an electrode layer 37 and an insulating layer 38.

The first semiconductor layer 31 of the light-emitting element ED may be an n-type semiconductor. The first semiconductor layer 31 may include a semiconductor material having the following chemical formula: AlₓGa_{y}In_{1-x-y}N (0≤x≤1, 0≤y≤1, 0≤x+y≤1). For example, the first semiconductor layer 31 may be one or more of AlGaInN, GaN, AlGaN, InGaN, AlN and InN doped with n-type dopant. The n-type dopant doped into the first semiconductor layer 31 may be Si, Ge, Sn, etc.

The second semiconductor layer 32 of the light-emitting element ED may be disposed above the first semiconductor layer 31 with the emissive layer 36 therebetween. The second semiconductor layer 32 may be a p-type semiconductor, and may include a semiconductor material having the following chemical formula: AlₓGa_{y}In_{1-x-y}N (0≤x≤1, 0≤y≤1, 0≤x+y≤1). For example, the second semiconductor layer 32 may be one or more of AlGaInN, GaN, AlGaN, InGaN, AlN and InN doped with p-type dopant. The p-type dopant doped into the second semiconductor layer 32 may be Mg, Zn, Ca, Ba, etc.

Although each of the first semiconductor layer 31 and the second semiconductor layer 32 is implemented as a signal layer in the drawings, the disclosure is not limited thereto. Depending on the material of the emissive layer 36, the first semiconductor layer 31 and the second semiconductor layer 32 may further include a larger number of layers, e.g., a clad layer or a tensile strain barrier reducing (TSBR) layer.

The emissive layer 36 of the light-emitting element ED may be disposed between the first semiconductor layer 31 and the second semiconductor layer 32. The emissive layer 36 may include a material having a single or multiple quantum well structure. In case that the emissive layer 36 includes a material having the multiple quantum well structure, the structure may include quantum layers and well layers alternately stacked on one another. The emissive layer 36 may emit light as electron-hole pairs are combined therein in response to an electrical signal applied through the first semiconductor layer 31 and the second semiconductor layer 32. The emissive layer 36 may include a material such as AlGaN, AlGaInN, and InGaN. In particular, in case that the emissive layer 36 has a multi-quantum well structure in which quantum layers and well layers are alternately stacked on one another, the quantum layers may include AlGaN or AlGaInN, and the well layers may include a material such as GaN and AlGaN.

The emissive layer 36 may have a structure in which a semiconductor material having a large band gap energy and a semiconductor material having a small band gap energy are alternately stacked on one another, and may include other Group III to Group V semiconductor materials depending on the wavelength range of the emitted light. The light emitted by the emissive layer 36 may be blue light having a peak wavelength in the blue wavelength band, i.e., in the range of 440 nm to 480 nm.

The electrode layer 37 of the light-emitting element ED may be an ohmic connection electrode. It is, however, to be understood that the disclosure is not limited thereto. The electrode layer 37 may be a Schottky connection electrode. The light-emitting element ED may include at least one electrode layer 37. The light-emitting element ED may include one or more electrode layers 37. It is, however, to be understood that the disclosure is not limited thereto. The electrode layer 37 may be eliminated.

The electrode layer 37 can reduce the resistance between the light-emitting element ED and the electrodes or the connection electrodes in case that the light-emitting element ED is electrically connected to the electrodes or the connection electrodes in the display device 1. The electrode layer 37 may include a metal having conductivity. For example, the electrode layer 37 may include at least one of aluminum (Al), titanium (Ti), indium (In), gold (Au), silver (Ag), ITO, IZO and ITZO.

The insulating film 38 of the light-emitting element ED can protect the semiconductor layers and the electrode layer of the light-emitting element ED. The insulating film 30 can prevent an electrical short-circuit that may occur in the emissive layer 36 if it comes in direct contact with an electrode through which an electric signal is transmitted to the light-emitting diode ED. In addition, the insulating film 38 can prevent a decrease in luminous efficiency.

The insulating film 38 may be disposed to surround the outer surfaces of the semiconductor layers and electrode layers described above. For example, the insulating film 38 may be disposed to surround at least the outer surface of the emissive layer 36, with both ends of the light-emitting element ED in the longitudinal direction exposed. In addition, a part of the upper surface of the insulating film 38 may be rounded in cross section, which may be adjacent to at least one of the ends of the light-emitting diode ED.

The insulating film 38 may include materials having insulating properties, for example, at least one of silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), and titanium oxide (TiOx). Although the insulating film 38 is formed as a single layer in the drawings, the disclosure is not limited thereto. In some embodiments, the insulating film 38 may be made up of a multilayer structure in which multiple layers are stacked on one another.

Referring back to FIG. 5, the connection electrodes CNE may be disposed on the alignment electrodes RME and the bank patterns. The connection electrodes CNE may each have a shape extended in a direction and may be spaced apart from one another. Each of the connection electrodes CNE may be in contact with the light-emitting elements ED and may be electrically connected to the alignment electrodes RME or the circuit element layer CCL thereunder (see FIG. 10).

The connection electrodes CNE may include a first connection electrode CNE1 and a second connection electrode CNE2 disposed in each sub-pixel SPXn.

The first connection electrode CNE1 may have a shape extended in the second direction DR2 and may be disposed on the first alignment electrode RME1 or the first bank pattern BP1. The first connection electrode CNE1 may partially overlap the first alignment electrode RME1 and may be disposed from the emission area EMA to the subsidiary area SA beyond the bank layer BNL.

The second connection electrode CNE2 may have a shape extended in the second direction DR2 and may be disposed on the second electrode RME2 or the second bank pattern BP2. The second connection electrode CNE2 may partially overlap the second alignment electrode RME2 and may be disposed from the emission area EMA to the subsidiary area SA beyond the bank layer BNL.

The first connection electrode CNE1 may be electrically connected to the first alignment electrode RME1 through a first contact CT1, and the second connection electrode CNE2 may be electrically connected to the second electrode RME2 through a second contact CT2.

Referring to FIG. 7, an electrode pattern layer 200 may be disposed on the bank layer BNL. The electrode pattern layer 200 may include a lattice pattern 210 surrounding the edges of the emission area EMA and/or the subsidiary area SA of each sub pixel SPXn, a slit pattern SL that forms slits SL in the emission area EMA, and a ground contact 250 that overlaps the second electrode contact hole CTS.

The lattice pattern 210 of the electrode pattern layer 200 may provide a path for discharging static electricity which may be generated in the display panel 300. The lattice pattern 210 may not overlap the emission area EMA of each sub-pixel SPXn in the third direction DR3 and may overlap the bank layer BNL in the third direction DR3.

The lattice pattern 210 may include first ground portions 210a extended in the first direction DR1 and second ground portions 210b extended in the second direction DR2. The first ground portions 210a and the second ground portions 210b may be parts of the lattice pattern 210. The first ground portions 210a may refer to parts of the lattice pattern 210 extended in the first direction DR1, and the second ground portion 210b may refer to parts of the lattice pattern 210 extended in the second direction DR2. The first ground portions 210a and the second ground portions 210b may be integrally formed at their intersections. In other words, the first ground portions 210a and the second ground portions 210b may share the intersections as parts of the lattice pattern 210.

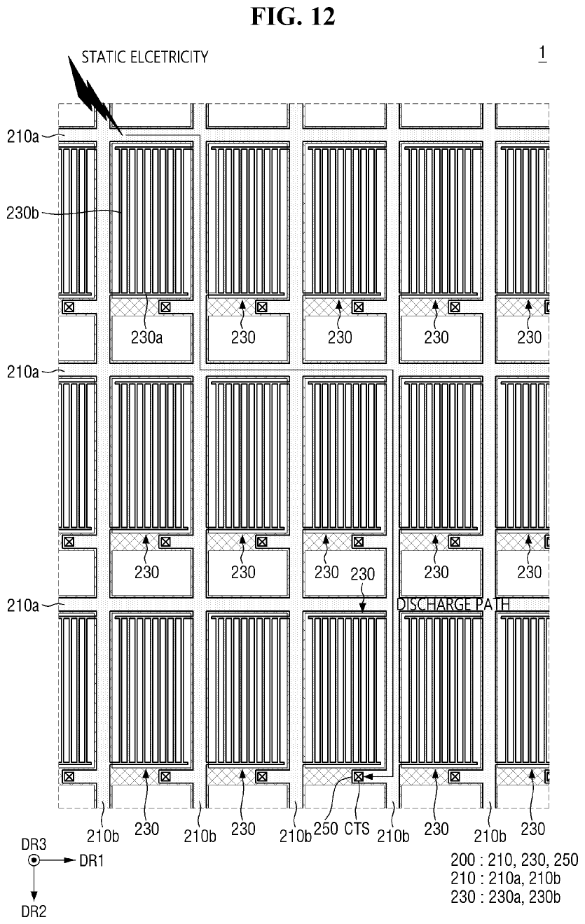

The first ground portion 210a may be extended in the second direction DR to cross the edges of each sub-pixel SPXn in the first direction DR1. The first ground portion 210a may traverse the edges of the sub-pixels SPXn in the first direction DR1 which are arranged in the second direction DR2 (see FIG. 12).

The second ground portion 210b may be extended in the first direction DR1 to cross the opposite edge of the emission area EMA of each sub-pixel SPXn in the second direction DR2 and the edge of the subsidiary area SA in the second direction DR2. The second ground portion 210b may traverse the opposite edges of the emission areas EMA of the sub-pixels SPXn repeatedly arranged in the first direction DR1 and the edge of the subsidiary area SA in the second direction DR2 (see FIG. 12).

The slit pattern 230 and the ground contact 250 may be disposed in each of the areas defined by the first ground portions 210a and the second ground portions 210b of the lattice pattern 210, i.e., in each of the area surrounding the edges of the emission area EMA and/or the subsidiary area SA adjacent thereto.

The slit pattern 230 of the electrode pattern layer 200 may be disposed to overlap the emission area EMA of each sub pixel SPXn in the third direction DR3 to scatter light output from the light-emitting elements ED. The slit pattern 230 may include a first scattering member 230a extended in the first direction DR1 and a second scattering member 230b extended in the second direction DR2.

The first scattering member 230a of the slit pattern 230 may be disposed adjacent to the ends of the emission area EMA in the second direction DR2. For example, two first scattering members 230a may be disposed at an end and the opposite end of the emission area EMA of each sub-pixel SPXn in the second direction DR2. It should be understood, however, that the disclosure is not limited thereto. For convenience of illustration, the first scattering member 230a disposed on one side of the emission area EMA in the second direction DR2 will be referred to as an upper first scattering member, while the first scattering member 230a disposed on the opposite side of the emission area EMA in the second direction DR2 will be referred to as a lower first scattering member.

Multiple second scattering members 230b of the slit pattern 230 may be arranged in the first direction DR1 between the upper first scattering members and the lower first scattering members. In other words, the second scattering members 230b may overlap the emission area EMA in the third direction DR3 and may be spaced apart from one another in the first direction DR1. The opposite side of each of the second scattering members 230b in the second direction DR2 may be in contact with the upper first scattering member, and the one side of each of the second scattering members 230b in the second direction DR2 may be in contact with the lower first scattering member.

The spaces between the second scattering members 230b may be defined as slits SL. Accordingly, the slits SL may be extended in the second direction DR2 by following the shape of the second scattering member 230b. In other words, the extending direction of the slits SL may cross the extending direction of the light-emitting elements ED, i.e., the first direction DR1.

The second scattering members 230b arranged on the emission area EMA in which the light-emitting elements ED are disposed can scatter light output from the light-emitting elements ED. In some embodiments, the length of each of the second scattering members 230b in the second direction DR2 may be at least greater than the length of the space in which the light-emitting elements ED are arranged in the second direction DR2. In some embodiments, at least one of the second scattering members 230b may overlap the emission area ED in the third direction DR3 to effectively scatter light output from the light-emitting elements ED. It should be understood, however, that the disclosure is not limited thereto.

The ground contact 250 of the electrode pattern layer 200 may electrically connect to the driving chip DC so that static electricity flowing through the lattice pattern 210 can be discharged. The ground contact 250 may be a part of the lattice pattern 210 that protrudes from and is electrically connected to the lattice pattern 210. The ground contact 250 may overlap the second electrode contact hole CTS in the third direction DR3. For example, the ground contact 250 may protrude from the opposite side of the second ground portion 210b in the first direction DR1 to be extended in the first direction DR1 such that it traverses between one side of the emission area EMA in the second direction DR2 and the opposite side of the subsidiary area SA in the second direction DR2 that is disposed on the one side of the emission area in the second direction DR2, and may not be extended to the adjacent second ground portion 210b. It should be understood, however, that the disclosure is not limited thereto. It should be noted that the first ground pattern portion 210a, the second ground portion 210b and the ground contact 250 of the lattice pattern 210 may be recited as ground electrodes in the claims.

The ground contact 250 may be electrically connected to the second alignment electrode RME2 through the second electrode contact hole CTS. The second alignment electrode RME2 may be connected to the second voltage line VL2 of the circuit element layer CCL as shown in FIG. 10 through the second electrode contact hole CTS, and the second voltage line VL2 may be electrically connected to the driving chip DC mounted on the flexible printed circuit board COF as described above, and thus the ground contact 250 may be electrically connected to the driving chip DC.

The lattice pattern 210, the slit pattern 230 and the ground contact 250 may be integrally formed via a single process. Accordingly, the lattice pattern 210, the slit pattern 230 and the ground contact 250 may include the same material. In some embodiments, the lattice pattern 210, the slit pattern 230 and the ground contact 250 may include a transparent conductive oxide (TCO) such as ITO, IZO and/or ITZO. Accordingly, it may be possible to prevent that the electrode pattern layer 200 is deteriorated by a subsequent process performed after the electrode pattern layer 200 has been formed during the process of fabricating the display device 1 according to an embodiment, and it may be possible to scatter the light output from the light-emitting elements ED by the slit pattern 230 and to prevent the light output from the light-emitting elements ED from being absorbed or reflected. In this manner, the light-emitting efficiency of the pixels PX can be improved.

Referring to FIG. 8, wavelength control areas LA1, LA2 and LA3 and a light-blocking area BA surrounding the wavelength control areas LA1, LA2 and LA3 may be disposed on the electrode pattern layer 200.

The wavelength control areas may include a first wavelength control area LA1, a second wavelength control area LA2, and a third wavelength control area LA3. The first wavelength control area LA1 may convert the wavelength of light output from the light-emitting elements ED into red light having a peak wavelength in the range of 610 nm to 650 nm, the second wavelength control area LA2 may convert the wavelength of light output from the light-emitting elements ED into green light having a peak wavelength in the range of 510 nm to 550 nm, and the third wavelength control area LA3 may transmit the wavelength of light output from the light-emitting elements ED as is.

Each of the wavelength control areas LA1, LA2 and LA3 may overlap the emission area EMA of each sub-pixel SPXn. For example, the first wavelength control area LA1 may overlap the emission area EMA of the first sub-pixel SPX1 in the third direction DR3, the second wavelength control area LA2 may overlap the emission area EMA of the second sub-pixel SPX2 in the third direction DR3, and the third wavelength control area LA3 may overlap the emission area EMA of the third sub-pixel SPX3 in the third direction DR3.

The light-blocking area BA may overlap the bank layer BNL and can block light output from the light-emitting elements ED from being recognized from the outside.

Hereinafter, the stack structure of the display device 1 according to an embodiment will be described.

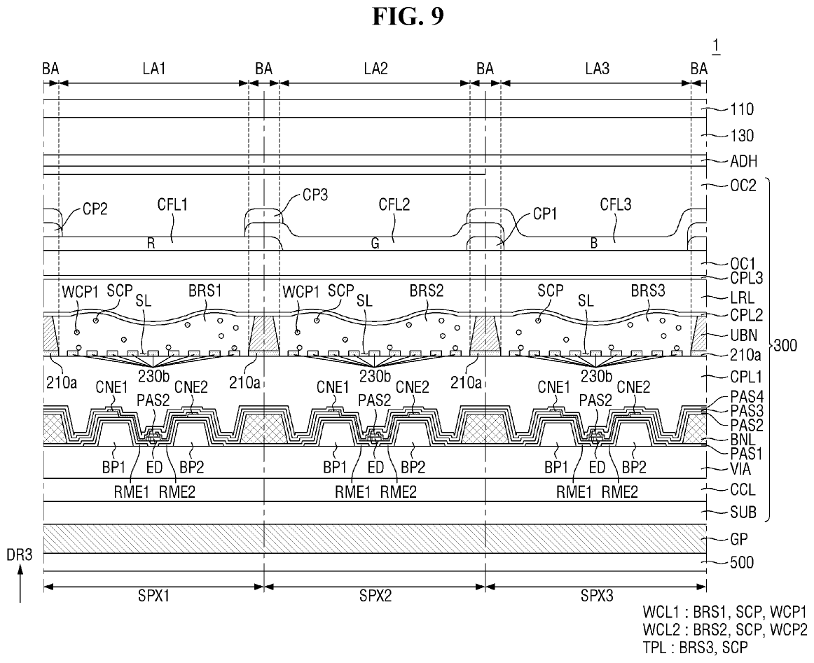

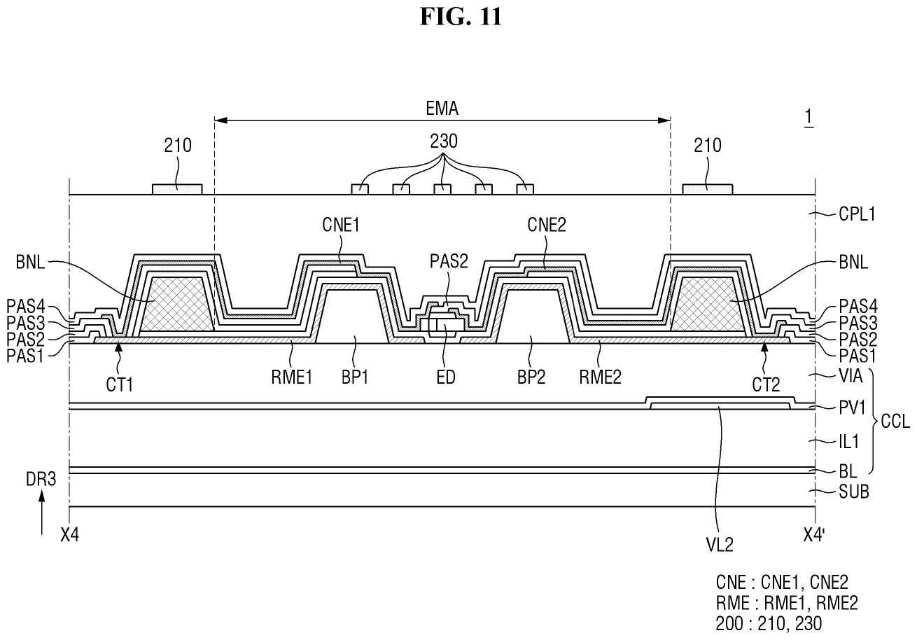

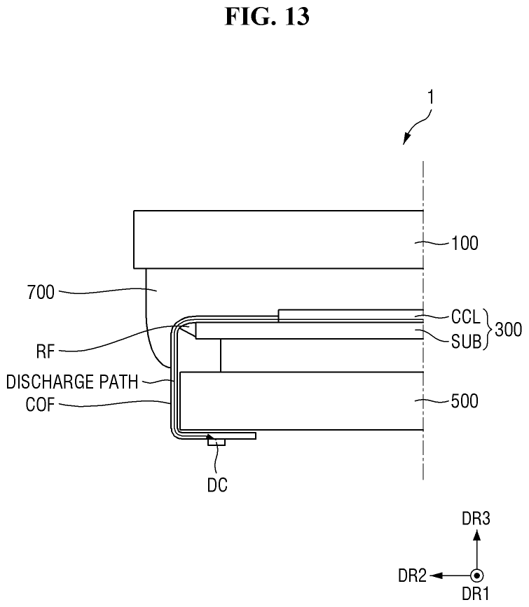

FIG. 9 is a cross-sectional view schematically showing a cross-section taken along line X2-X2′ of FIGS. 5, 6 and 8. FIG. 10 is a cross-sectional view schematically showing a cross-section taken along line X3-X3′ of FIGS. 5 and 8. FIG. 11 is a cross-sectional view schematically showing a cross-section taken along line X4-X4′ of FIGS. 5 and 8. FIGS. 12 and 13 are views schematically illustrating paths via which static electricity is discharged through the electrode pattern layer of the display device according to an embodiment.

Referring to FIGS. 9 to 13, the display panel 300 may include a substrate SUB, a circuit element layer CCL, a via insulating layer VIA, bank patterns BP1 and BP2, a first passivation layer PAS1, alignment electrodes RME, a bank layer BNL, a second passivation layer PAS2, light-emitting elements ED, connection electrodes CNE, a third passivation layer PAS3, a fourth passivation layer PAS4, a first capping layer CPL1, an electrode pattern layer 200, an upper bank layer UBN, color control structures WCL1, WCL2 and TPL, a second capping layer CPL2, a low-refractive layer LRL, a second capping layer CPL2, a first overcoat layer OC1, a color filter layer CFL (CF1, CF2, CF3), and a second overcoat layer OC2.

The substrate SUB may work as a base of the display panel 300. The substrate SUB may be made of an insulating material such as glass, quartz and/or a polymer resin. In addition, the substrate SUB may be either a rigid substrate or a flexible substrate that can be bent, folded, and/or rolled. The bottom of the substrate SUB may be the bottom of the display panel 300.

The circuit element layer CCL may be disposed on the substrate SUB. In the circuit element layer CCL, a variety of lines may be disposed, which transmit electrical signals to the light-emitting elements disposed on the substrate SUB. As shown in FIGS. 10 and 11, the circuit element layer CCL may include conductive layers such as, a first conductive layer, a semiconductor layer, a second conductive layer, a third conductive layer, etc., and may include a buffer layer BL, a first gate insulator GI, a first interlayer dielectric layer IL1, and a first passivation layer PV1 as insulating layers.

A first conductive layer may be disposed on the substrate SUB. The first conductive layer may include a bottom metal layer BML. The bottom metal layer BML may be disposed to overlap an active layer ACT1 of a first transistor T1. The bottom metal layer BML may prevent light from being incident on the first active layer ACT1 of the first transistor or may be electrically connected to the first active layer ACT1 to stabilize the electrical characteristics of the first transistor T1. It is, however, to be noted that the bottom metal layer BML may be eliminated.

A buffer layer BL may be disposed on the bottom metal layer BML and the substrate SUB. The buffer layer BL may be formed on the substrate SUB to protect the transistors of the pixels PX from moisture permeating through the substrate SUB, which may be susceptible to moisture permeation, and may also provide a flat surface.

The semiconductor layer may be disposed on the buffer layer BL. The semiconductor layer may include the first active layer ACT1 of the first transistor T1 and the second active layer ACT2 of the second transistor T2. The first active layer ACT1 and the second active layer ACT2 may be disposed to partially overlap the first gate electrode G1 and the second gate electrode G2 of a second conductive layer, respectively, which will be described later.

The semiconductor layer may include polycrystalline silicon, monocrystalline silicon, an oxide semiconductor, etc. In other embodiments, the semiconductor layer may include polycrystalline silicon. The oxide semiconductors may be one or more oxide semiconductors selected from G-I—Z—O, zinc (Zn), indium (In), gallium (Ga), tin (Sn) cadmium (Cd), germanium (Ge) hafnium (Hf), or a combination thereof. For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), indium-gallium zinc tin oxide (IGZTO), etc.

Although the first transistor T1 and the second transistor T2 are disposed in the sub-pixel SPXn of the display device 1 in FIG. 11, the disclosure is not limited thereto. A larger number of transistors may be included in the display device 1.

The first gate insulator GI may be disposed on the semiconductor layer in the display area DA. The first gate insulator GI may work as a gate insulating film of the transistors T1 and T2. In the example shown in the drawings, the first gate insulator GI is patterned together with the gate electrodes G1 and G2 of the second conductive layer to be described later, and is partially disposed between the second conductive layer and the active layers ACT1 and ACT2 of the semiconductor layer. It is, however, to be understood that the disclosure is not limited thereto. In some embodiments, the first gate insulator GI may be disposed entirely on the buffer layer BL.

The second conductive layer may be disposed on the first gate insulator GI. The second conductive layer may include a first gate electrode G1 of the first transistor T1, and a second gate electrode G2 of the second transistor T2. The first gate electrode G1 may overlap a channel region of the first active layer ACT1 in the third direction DR3, which is the thickness direction. The second gate electrode G2 may overlap a channel region of the second active layer ACT2 in the third direction DR3, which is the thickness direction.

A first interlayer dielectric layer IL1 may be disposed on the second conductive layer. The first interlayer dielectric layer IL1 may work as an insulating film between the second conductive layer and other layers disposed thereon and can protect the second conductive layer.

The third conductive layer may be disposed on the first interlayer dielectric layer ILL The third conductive layer may include the first voltage line VL1 and the second voltage line VL2 disposed in the display area DA, a first conductive pattern CDP1, and the source electrodes S1 and S2 and drain electrodes D1 and D2 of the transistors T1 and T2.

A high-level voltage (or a first supply voltage) may be applied to the first voltage line VL1 to be transmitted to the first alignment electrode RME1, and a low-level voltage (or a second supply voltage) may be applied to the second voltage line VL2 to be transmitted to the second alignment electrode RME2. A part of the first voltage line VL1 may be in contact with the first active layer ACT1 of the first transistor T1 through a contact hole penetrating the first interlayer dielectric layer IL1. The first voltage line VL1 may work as the first drain electrode D1 of the first transistor T1. The second voltage line VL2 may be directly connected to the second alignment electrode RME2 to be described later.

The first conductive pattern CDP1 may be in contact with the first active layer ACT1 of the first transistor T1 through a contact hole penetrating the first interlayer dielectric layer ILL The first conductive pattern CDP1 may be in contact with the bottom metal layer BML through another contact hole penetrating the first interlayer dielectric layer IL1 and the buffer layer BL. The first conductive pattern CD1 may work as a first source electrode S1 of the first transistor T1. In addition, the first conductive pattern CDP1 may be connected to a first alignment electrode RME1 or a first connection electrode CNE1 to be described later. The first transistor T1 may transfer the first supply voltage applied from the first voltage line VL1 to the first alignment electrode RME1 or the first connection electrode CNE1.

Each of the second source electrode S2 and the second drain electrode D2 may be in contact with the second active layer ACT2 of the second transistor T2 through contact holes penetrating the first interlayer dielectric layer ILL

A first passivation layer PV1 may be disposed over the third conductive layer. The first passivation layer PV1 may work as an insulating film between the third conductive layer and other layers and can protect the third conductive layer.

The buffer layer BL, the first gate insulating layer GI, the first interlayer dielectric layer IL1 and the first passivation layer PV1 may be made up of multiple inorganic layers stacked on one another alternately. For example, the buffer layer BL, the first gate insulating layer GI, the first interlayer dielectric layer IL1 and the first passivation layer PV1 may be made up of a double layer in which inorganic layers including at least one of silicon oxide (SiOx), silicon nitride (SiNx) and silicon oxynitride (SiON) are stacked on one another or multiple layers in which they are alternately stacked on one another.

The via insulating layer VIA may be disposed on the circuit element layer CCL. Specifically, the via insulating layer VIA may be disposed on the first passivation layer PV1 of the circuit element layer CCL. The via insulating layer VIA may include an organic insulating material, e.g., an organic insulating material such as polyimide (PI), to provide a flat surface over a variety of lines having different heights in the circuit element layer CCL. It should be noted that the via insulating layer VIA may be eliminated in some implementations.

The bank patterns BP1 and BP2 may be disposed on the via insulating layer VIA. For example, the bank patterns BP1 and BP2 may be disposed directly on the via insulating layer VIA, and may have a structure that at least partly protrudes from the upper surface of the via insulating layer VIA. The protruding portions of the bank patterns BP1 BP2 may have inclined side surfaces or bent side surfaces with a predetermined or given curvature. The light emitted from the light-emitting elements ED may be reflected by the alignment electrodes RME disposed on the bank patterns BP1 and BP2 so that the lights may exit toward the upper side of the via insulating layer VIA. The bank patterns BP1 and BP2 may include, but are not limited to, an organic insulating material such as polyimide (PI).

The alignment electrodes RME: RME1 and RME2 may be disposed on the bank patterns BP1 and BP2 and the via insulating layer VIA. For example, the first alignment electrode RME1 and the second alignment electrode RME2 may be disposed on at least inclined side surfaces of the bank patterns BP1 and BP2. The width of the alignment electrodes RME measured in the second direction DR2 may be smaller than the width of the bank patterns BP1 and BP2 measured in the second direction DR2. The distance between the first alignment electrode RME1 and the second alignment electrode RME2 spaced apart from each other in the second direction DR2 may be smaller than the distance between the bank patterns BP1 and BP2. At least a part of the first alignment electrode RME1 and the second alignment electrode RME2 may be disposed directly on the via insulating layer VIA, so that they may be disposed on a same plane.

The light-emitting elements ED disposed between the bank patterns BP1 and BP2 may emit lights through the ends. The emitted light may be directed to the alignment electrodes RME disposed on the bank patterns BP1 and BP2.

The part of each of the alignment electrodes RME that is disposed on the bank patterns BP1 and BP2 may reflect light emitted from the light-emitting elements ED. The first alignment electrodes RME1 and the second alignment electrodes RME2 may be disposed to cover the side surfaces of the bank patterns BP1 and BP2 on at least one side to reflect light emitted from the light-emitting elements ED.

Each of the alignment electrodes RME may be in direct contact with the third conductive layer through the electrode contact holes CTD and CTS where overlapping the bank layer BNL. The first electrode contact hole CTD may be formed where the bank layer BNL and the first alignment electrode RME1 overlap each other. The second electrode contact hole CTS may be formed where the bank layer BNL and the second alignment electrode RME2 overlap each other. The first alignment electrode RME1 may be in contact with the first conductive pattern CDP1 through the first electrode contact hole CTD penetrating through the via insulating layer VIA and the first passivation layer PV1. The second alignment electrode RME2 may be in contact with the second voltage line VL2 through the second electrode contact hole CTS penetrating through the via insulating layer VIA and the first passivation layer PV1. The first alignment electrode RME1 may be electrically connected to the first transistor T1 through the first conductive pattern CDP1 to receive the first supply voltage. The second alignment electrode RME2 may be electrically connected to the second voltage line VL2 to receive the second supply voltage. It is, however, to be understood that the disclosure is not limited thereto. According to another embodiment, each of the alignment electrodes RME1 and RME2 may not be electrically connected to the voltage lines VL1 and VL2 of the third conductive layer and connection electrodes CNE to be described later and may be directly connected to the third conductive layer.

Each of the alignment electrodes RME may include a conductive material having a high reflectance. For example, the alignment electrodes RME may include a metal such as silver (Ag), copper (Cu) and/or aluminum (Al), and/or may include an alloy including aluminum (Al), nickel (Ni), lanthanum (La), and/or the like, and/or a stack of a metal layer such as titanium (Ti), molybdenum (Mo) and niobium (Nb) and the alloy. In some embodiments, the alignment electrodes RME may be made up of a double- or multi-layer in which an alloy containing aluminum (Al) and at least one metal layer made of titanium (Ti), molybdenum (Mo) and niobium (Nb) are stacked on one another.

It is, however, to be understood that the disclosure is not limited thereto. The alignment electrodes RME may further include a transparent conductive material. For example, each of the alignment electrodes RME may include a material such as ITO, IZO and/or ITZO. In some embodiments, each of the alignment electrodes RME1 and RME2 may have a structure in which one or more layers of a transparent conductive material and one or more metal layers having high reflectivity are stacked on one another, or may be made up of a single layer including them. For example, each of the alignment electrodes RME may have a stack structure such as ITO/Ag/ITO/, ITO/Ag/IZO, or ITO/Ag/ITZO/IZO. The alignment electrodes RME may be electrically connected to the light-emitting elements ED and may reflect some of the light emitted from the light-emitting elements ED toward the upper side of the substrate SUB.

The first passivation layer PAS1 may be disposed on the front surface of the display area DA, and may be disposed on the via insulating layer VIA and the alignment electrodes RME. The first passivation layer PAS1 may include an insulating material, and can protect the alignment electrodes RME and can insulate different alignment electrodes RME from one another. As the first passivation layer PAS1 is disposed to cover the alignment electrodes RME before the bank layer BNL is formed, it may be possible to prevent the alignment electrode RME from being damaged during the process of forming the bank layer BNL. In addition, the first passivation layer PAS1 can also prevent that the light-emitting diodes ED disposed thereon are brought into contact with other elements and damaged.

In an embodiment, the first passivation layer PAS1 may have steps so that a part of the upper surface is recessed between the alignment electrodes RME spaced apart from one another in the second direction DR2. The light-emitting diodes ED may be disposed at the steps of the upper surface of the first passivation layer PAS1, and space may be formed between the light-emitting diodes ED and the first passivation layer PAS1.

The first passivation layer PAS1 may include contacts CT1 and CT2 as shown in FIG. 10. The contacts may be located such that they overlap different alignment electrodes RME, respectively. For example, the contacts may include a first contact CT1 overlapping the first alignment electrode RME1 and a second contact CT2 overlapping the second alignment electrode RME2. The first contact CT1 and the second contact CT2 may penetrate the first passivation layer PAS1 to expose a part of the upper surface of the first alignment electrode RME1 or the second alignment electrode RME2 disposed thereunder. Each of the first contact CT1 and the second contact CT2 may further penetrate some of the other insulating layers disposed on the first passivation layer PAS1. The alignment electrodes RME exposed by the contacts may be in contact with the connection electrodes CNE.

The bank layer BNL may be disposed on the first passivation layer PAS1. In some embodiments, the bank layer BNL may overlap the first electrode contact hole CTD or the second electrode contact hole CTS in the third direction DR3, but the disclosure is not limited thereto. For example, the bank layer BNL may not overlap the first electrode contact hole CTD or the second electrode contact hole CTS in the third direction DR3.

The light-emitting elements ED may be electrically connected to the alignment electrodes RME and the conductive layers under the via insulating layer VIA in contact with the connection electrodes CNE: CNE1 and CNE2, and an electric signal may be applied to it so that light of a particular wavelength range can be emitted.

The bank layer BNL may have a predetermined or given height similar to the bank patterns BP1 and BP2. In some embodiments, the top surface of the bank layer BNL may have a height higher than that of the bank patterns BP1 and BP2, and the thickness thereof may be equal to or greater than the thicknesses of the bank patterns BP1 and BP2. The bank layer BNL can prevent an ink from overflowing into adjacent sub-pixels SPXn during an inkjet printing process of the process of fabricating the display device 1. The bank layer BNL may include an organic insulating material such as polyimide, like the bank patterns BP1 and BP2.

The second passivation layer PAS2 may be disposed on the light-emitting elements ED, the first passivation layer PAS1 and the bank layer BNL. The second passivation layer PAS2 may be extended in the first direction DR1 between the bank patterns BP1 and BP2 and may include a pattern portion disposed on the plurality of light-emitting elements ED. The pattern portion may be disposed to partially surround the outer surface of the light-emitting diodes ED, and may not cover both sides or both ends of the light-emitting diodes ED. The pattern portion may form a linear or island pattern in each sub-pixel SPXn in plan view. The pattern portion of the second passivation layer PAS2 can protect the light-emitting elements ED and can fix the light-emitting elements ED during the process of fabricating the display device 1. In addition, the second passivation layer PAS2 may be disposed to fill the space between light-emitting diodes ED and the first passivation layer PAS1 thereunder. In addition, a part of the second passivation layer PAS2 may be disposed on the bank layer BNL.

The second passivation layer PAS2 may include contacts CT1 and CT2. For example, the second passivation layer PAS2 may include a first contact CT1 overlapping the first alignment electrode RME1 and a second contact CT2 overlapping the second alignment electrode RME2. The contacts may penetrate through the second passivation layer PAS2 in addition to the first passivation layer PAS1. Each of the first contact CT1 and the second contact CT2 may expose a part of the upper surface of the first alignment electrode RME1 or the second alignment electrode RME2 thereunder.

The third passivation layer PAS3 may be disposed on the second passivation layer PAS2. The third passivation layer PAS3 may be disposed entirely on the second passivation layer PAS2 to cover the second connection electrode CNE2, and one of the ends of the light-emitting elements ED may be exposed. As will be described later, the second connection electrode CNE2 of the connection electrode CNE may be in contact with first ends of the light-emitting elements ED that are not exposed by the third passivation layer PAS3, while the first connection electrode CNE1 may be in contact with other ends of the light-emitting elements ED that are exposed by the third passivation layer PAS3. The third passivation layer PAS3 may insulate the first connection electrode CNE1 and the second connection electrode CNE2 from each other so that they are not in direct contact with each other.

The third passivation layer PAS3 may include the first contact CT1. The first contact CT1 may penetrate through the third passivation layer PAS3 in addition to the first passivation layer PAS1 and the second passivation layer PAS2. The first contacts CT1 may expose a part of the upper surface of the first electrode RME1 thereunder.

The connection electrodes CNE; CNE1 and CNE2 may be disposed such that they at least partially overlap the alignment electrodes RME and the bank patterns BP1 and BP2 in the third direction DR3. The first connection electrode CNE1 may be disposed to overlap the first alignment electrode RME1 and the first bank pattern BP1 in the third direction DR3. The first connection electrode CNE1 may at least partially overlap the first alignment electrode RME1 and may be extended from the emission area EMA beyond the bank layer BNL. The second connection electrode CNE2 may be disposed to overlap the second alignment electrode RME2 and the second bank pattern BP2 in the third direction DR3. The second connection electrode CNE2 may at least partially overlap the second alignment electrode RME2 and may be extended from the emission area EMA beyond the bank layer BNL.

The first connection electrode CNE1 may be disposed on the third passivation layer PAS3, and the second connection electrode CNE2 may be disposed on the second passivation layer PAS2 to be in contact with the light-emitting elements ED. For example, the first connection electrode CNE1 may partially overlap the first alignment electrode RME1 and may be in contact with ends (hereinafter referred to as “first ends”) of the light-emitting elements ED, and the second connection electrode CNE2 may partially overlap the second alignment electrode RME2 and may be in contact with other ends (hereinafter referred to as “second ends”) of the light-emitting elements ED.

The connection electrodes CNE may be in contact with the light-emitting elements ED and may be electrically connected to the third conductive layer. For example, in the display device 1, the connection electrodes CNE may be in contact with the alignment electrodes RME through the contacts CT1 and CT2. The first connection electrode CNE1 may be in contact with the first alignment electrode RME1 through the first contact CT1 penetrating the first passivation layer PAS1, the second passivation layer PAS2 and the third passivation layer PAS3. The second connection electrode CNE2 may be in contact with the second alignment electrode RME2 through the second contact CT2 penetrating the first passivation layer PAS1 and the second passivation layer PAS2. The connection electrodes CNE may be electrically connected to the third conductive layer through the respective alignment electrodes RME. The first connection electrode CNE1 may be electrically connected to the first transistor T1 to apply the first supply voltage, and the second connection electrode CNE2 may be electrically connected to the second voltage line VL2 to apply the second supply voltage. Accordingly, the first connection electrode CNE1 may be in contact with the first ends of the light-emitting elements ED to apply a first supply voltage to the first ends of the light-emitting elements ED, and the second connection electrode CNE2 may be in contact with the second ends of the light-emitting elements ED to apply a second supply voltage to the second ends of the light-emitting elements ED.

The connection electrodes CNE may include a conductive material. For example, the connection electrodes CNE may include ITO, IZO, ITZO, aluminum (Al), etc. For example, the connection electrodes CNE may include a transparent conductive material, and light emitted from the light-emitting elements ED may transmit the connection electrodes CNE to exit.

The fourth passivation layer PAS4 may be disposed on the third passivation layer PAS3, the connection electrodes CNE1 and CNE2, and the bank layer BNL. The fourth passivation layer PAS4 can protect the layers disposed on the substrate SUB. It is to be noted that the fourth passivation layer PAS4 may be eliminated.

Each of the above-described first passivation layer PAS1, second passivation layer PAS2, third passivation layer PAS3 and fourth passivation layer PAS4 may include an inorganic insulating material or an organic insulating material. According to an embodiment of the disclosure, each of the first passivation layer PAS1, the second passivation layer PAS2, the third passivation layer PAS3 and the fourth passivation layer PAS4 may be made of at least one of silicon oxide (SiOx), silicon nitride (SiNx), and silicon oxynitride (SiOxNy). The first passivation layer PAS1, the second passivation layer PAS2, the third passivation layer PAS3 and the fourth passivation layer PAS4 may be made of the same material. Alternatively, some of the passivation layers may be made of the same material while other(s) may be made of different material(s), or they may be made of different materials from one another.

The first capping layer CPL1 may be disposed on the fourth passivation layer PAS4. The first capping layer CPL1 can prevent light output from the light-emitting elements ED from deteriorating the color control structures TPL, WCL1 and WCL2, which will be described later. In general, the intensity of light output from the light-emitting elements ED is greater toward the light-emitting elements ED. Accordingly, by increasing the distance between the light-emitting elements ED and the color control structures TPL, WCL1 and WCL2, it may be possible to prevent the light output from the light-emitting elements ED from deteriorating the color control structures TPL, WCL1, and WCL2, which will be described later.

In other words, if the color control structures TPL, WCL1 and WCL2 are disposed directly on the light-emitting elements ED, the intensity of light output from the light-emitting elements ED is relatively strong, and thus the color control structures TPL, WCL1 and WCL2 may be deteriorated. In view of the above, the first capping layer CPL1 is disposed between the light-emitting elements ED and the color control structures TPL, WCL1 and WCL2, so that the intensity of light reaching the color control structures TPL, WCL1 and WCL2 can be reduced.

The first capping layer CPL1 may include an inorganic insulating material or an organic insulating material. In addition, the first capping layer CPL1 may provide a flat surface over the light-emitting elements ED, the bank patterns BP1 and BP2, and the bank layer BNL having different heights.

The electrode pattern layer 200 may be disposed on the first capping layer CPL1. The electrode pattern layer 200 may include the lattice pattern 210 that forms a discharge path of static electricity, the slit pattern 230 for scattering the light output from the light-emitting elements ED, and the ground contact 250 connected to the second voltage line VL2 through the second electrode contact hole CTS.

As described above, the lattice pattern 210 may overlap the bank layer BNL in the third direction DR3 and may not overlap the emission area EMA in the third direction DR3. In addition, the slit pattern 230 may overlap the emission area EMA in the third direction DR3.

Since at least a part of the slit pattern 230 overlaps the light-emitting elements ED in the third direction DR3, light output from the light-emitting elements ED may be scattered by the slit pattern 230 and may reach the color control structures TPL, WCL1 and WCL2 disposed on the electrode pattern 200. Accordingly, it may be possible to prevent damage to the color control structures TPL, WCL1 and WCL2 by the light output from the light-emitting elements ED, and to improve the light-emitting efficiency of the pixels PX.

The ground contact 250 may protrude from a part of the lattice pattern 210. The ground contact 250 may be in contact with a part of the second alignment electrode RME2 exposed by the second electrode contact hole CTS penetrating through the first capping layer CPL1, the fourth passivation layer PAS4, the third passivation layer PAS3, the second passivation layer PAS2, the bank layer BNL and the first passivation layer PAS1 and may be electrically connected to it. Accordingly, since the lattice pattern 210 is electrically connected to the ground contact 250, and the ground contact 250 is electrically connected to the second voltage line VL2, static electricity that may be generated in the display area DA can be discharged to the second voltage line VL2 by the lattice pattern 210 and the ground contact 250.

Specifically, as shown in FIGS. 12 and 13, static electricity generated in the vicinity of one sub-pixel SPXn may pass through the second voltage line VL2 via the contact 250 along the lattice pattern 210 surrounding the edge of the one sub-pixel SPXn, and may be discharged to the driving chip DC through the flexible printed circuit board COF via the second voltage line VL2.

With the above-described configuration, the electrode pattern layer 200 can scatter light output from the light-emitting elements ED to prevent deterioration of the color control structures TPL, WCL1 and WCL2, and can discharge static electricity to the outside which may be generated in the display panel 300.

Incidentally, the wavelength control areas LA1, LA2 and LA3 may be disposed on the first capping layer CPL1 and the electrode pattern layer 200. For example, on the first capping layer CPL1 and the electrode pattern layer 200, the upper bank layer UBN, the color control structures TPL, WCL1 and WCL2, the color patterns CP1, CP2 and CP3, and the color filter layers CFL1, CFL2 and CFL3 may be disposed. Multiple capping layers CPL2 and CPL3, the low-refractive layer LRL and the first overcoat layer OC1 may be disposed between the color control structures TPL, WCL1 and WCL2 and the color filter layers CFL1, CFL2 and CFL3, and the second overcoat layer OC2 may be disposed on the color filter layers CFL1, CFL2 and CFL3.

The upper bank layer UBN may be disposed on the fourth passivation layer PAS4 to overlap the bank layer BNL. The upper bank layer UBN may be disposed in a lattice pattern, including portions extended in the first direction DR1 and the second direction DR2 in plan view. The upper bank layer UBN may surround the emission area or a portion where the light-emitting elements ED are disposed. The upper bank layer UBN may define the space in which the color control structures TPL, WCL1 and WCL2 are disposed.

The color control structures TPL, WCL1 and WCL2 may be disposed on the fourth passivation layer PAS4 such that they are surrounded by the upper bank layer UBN. The color control structures TPL, WCL1, and WCL2 may be disposed in the wavelength control areas LA1, LA2 and LA3 surrounded by the upper bank layer UBN to form an island-shaped pattern in the display area DA. It should be understood, however, that the disclosure is not limited thereto. The color control structures TPL, WCL1, and WCL2 may be extended in a direction and disposed across the sub-pixels SPXn to form a linear pattern.

In an embodiment where the light-emitting elements ED of each of the sub-pixels PXn emit blue light of the third color, the color control structures TPL, WCL1 and WCL2 may include a first wavelength conversion layer WCL1 disposed in the first sub-pixel SPX1 in line with the first wavelength control area LA1, a second wavelength conversion layer WCL2 disposed in the second sub-pixel SPX2 in line with the second wavelength control area LA2, and a transparent layer TPL disposed in the third sub-pixel SPX3 in line with the third wavelength control area LA3.

The first wavelength conversion layer WCL1 may include a first base resin BRS1 and first wavelength-converting particles WCP1 dispersed in the first base resin BRS1. The second wavelength conversion layer WCL2 may include a second base resin BRS2 and second wavelength-converting particles WCP2 dispersed in the second base resin BRS2. The first wavelength conversion layer WCL1 and the second wavelength conversion layer WCL2 convert and transmit the wavelength of the blue light of the third color incident from the light-emitting diodes ED. The first wavelength conversion layer WCL1 and the second wavelength conversion layer WCL2 may further include scattering particles SCP included in each base resin, and the scattering particles SCP can increase wavelength conversion efficiency.

The transparent layer TPL may include a base resin BRS3 and scattering particles SCP dispersed in the third base resin BRS3. The transparent layer TPL transmits the wavelength of the blue light of the third color incident from the light-emitting diodes ED as is. The scattering particles SCP of the transparent layer TPL may adjust an emission path of exiting light through the transparent layer TPL. The transparent layer TPL may include no wavelength conversion material.

The scattering particles SCP may be metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), etc. Examples of the material of the organic particles may include an acrylic resin, a urethane resin, etc.

The first to third base resins BRS1, BRS2 and BRS3 may include a transparent organic material. For example, the first to third base resins BRS1, BRS2 and BRS3 may include an epoxy resin, an acrylic resin, a cardo resin, an imide resin, and/or the like. The first to third base resins BRS1, BRS2 and BRS3 may be made of, but are not limited to, the same material.

The first wavelength-converting particles WCP1 may convert the blue light of the third color into the red light of the first color, and the second wavelength-converting particles WCP2 may convert the blue light of the third color into the green light of the second color. The first wavelength-converting particles WCP1 and the second wavelength-converting particles WCP2 may be quantum dots, quantum rods, phosphors, etc. The quantum dots may include IV nanocrystals, II-VI compound nanocrystals, III-V compound nanocrystals, IV-VI nanocrystals, or combinations thereof.

In some embodiments, the color control structures TPL, WCL1 and WCL2 may be formed via an inkjet printing process or a photoresist process. The color control structures TPL, WCL1 and WCL2 may be formed via drying or exposure and development processes after a material forming the color control structures is sprayed or applied in the space surrounded by the upper bank layer UBN. For example, in an embodiment in which the color control structures TPL, WCL1 and WCL2 are formed via an inkjet printing process, the upper surface of each layer of the color control structures TPL, WCL1 and WCL2 may be formed to be curved, so that the edge thereof that may be adjacent to the upper bank layer UBN may be higher than the center thereof in the drawings. It is, however, to be understood that the disclosure is not limited thereto. In an embodiment where the color control structures TPL, WCL1 and WCL2 are formed via a photoresist process, the upper surface of each layer of the color control structures TPL, WCL1 and WCL2 may be formed to be flat so that the edge that may be adjacent to the upper bank layer UBN may be parallel to the upper surface of the upper bank layer UBN, or the center of the color control structures TPL, WCL1 and WCL2 may be higher than it, unlike the example shown in the drawings.

While the light-emitting elements ED of different sub-pixels SPXn may emit light of the same color, i.e., the blue light of the third color, the lights of different colors may exit from the different sub-pixels SPXn. For example, the light emitted from the light-emitting diodes ED disposed in the first sub-pixel SPX1 may be incident on the first wavelength conversion layer WCL1, the light emitted from the light-emitting diodes ED disposed in the second sub-pixel SPX2 may be incident on the second wavelength conversion layer WCL2, and the light emitted from the light-emitting diodes ED disposed in the third sub-pixel SPX3 may be incident on the transparent layer TPL. The light incident on the first wavelength conversion layer WCL1 may be converted into red light, the light incident on the second wavelength conversion layer WCL2 may be converted into green light, and the light incident on the transparent layer TPL may transmit it as the same blue light without wavelength conversion. Although the sub-pixels SPXn include the light-emitting diodes ED that emit light of the same color, light of different colors can be output by disposing the color control structures TPL, WCL1 and WCL2 over them.

The second capping layer CPL2 may be disposed on the color control structures TPL, WCL1 and WCL2 and the upper bank layer UBN. The second capping layer CPL2 can prevent impurities such as moisture and air from being introduced from the outside to damage or contaminate the color control structures TPL, WCL1 and WCL2. The second capping layer CPL2 may include an inorganic insulating material.

The low-refractive layer LRL may be disposed on the second capping layer CPL2. The low-refractive layer LRL may be an optical layer that recycles lights which have passed through the color control structures TPL, WCL1 and WCL2, and can improve the emission efficiency and the color purity of the display device 1. The low-refractive layer LRL may be made of an organic material having a low refractive index, and may provide a flat surface over the color control structures TPL, WCL1 and WCL2 and the upper bank layer UBN having different heights.

The third capping layer CPL3 may be disposed on the low-refractive layer LRL, and can prevent impurities such as moisture and air from penetrating from the outside to damage or contaminate the low-refractive layer LRL. The third capping layer CPL3 may include an inorganic insulating material similar to the second capping layer CPL2.

The first overcoat layer OC1 may be disposed across the entire display area DA and the entire non-display area NDA on the third capping layer CPL3. The first overcoat layer OC1 may overlap the color control structures TPL, WCL1, and WCL2 in the display area DA.

The first overcoat layer OC1 can protect the elements disposed on the substrate SUB, in addition to the capping layers CPL1 and CPL2 and the low-refractive layer LRL, and can partially provide a flat surface over them having different heights. In particular, the first overcoat layer OC1 may provide a flat surface over the color control structures TPL, WCL1, and WCL2, the upper bank layer UBN and the bank layer BNL thereunder which may have different heights in the display area DA, so that the color filter layers CFL1, CFL2 and CFL3 can be formed on the flat surface.

The color filter layers CFL1, CFL2 and CFL3 may be disposed on the first overcoat layer OC1. The color filter layers CFL1, CFL2 and CFL3 may be disposed in the wavelength control area LA1, LA2 and LA3, respectively, and may be partially disposed in the light-blocking area BA. The color filter layers CFL1, CFL2 and CFL3 may overlap other color filter layers CFL1, CFL2 and CFL3 or the color patterns CP1, CP2 and CP3 in the light-blocking area BA. The wavelength control areas LA1, LA2 and LA3 from which light is output may be where the color filter layers CFL1, CFL2 and CFL3 do not overlap other color filter layers CFL1, CFL2 and CFL3. The light-blocking area BA in which light may be blocked may be where different color filter layers CFL1, CFL2 and CFL3 overlap each other or the color patterns CP1, CP2 and CP3 are disposed.

The color filter layers CFL1, CFL2 and CFL3 may include a first color filter layer CFL1 disposed in the first sub-pixel SPX1, a second color filter layer CFL2 disposed in the second sub-pixel SPX2, and a third color filter layer CFL3 disposed in the third sub-pixel SPX3. The color filter layers CFL1 CFL2 and CFL3 may be formed in a linear pattern disposed in the wavelength control areas LA1, LA2 and LA3. It is, however, to be understood that the disclosure is not limited thereto. The color filter layers CFL1, CFL2 and CFL3 may be disposed in the wavelength control areas LA1, LA2 and LA3, respectively, and may form an island-shaped pattern.

The color filter layers CFL1, CFL2 and CFL3 may include a colorant such as a dye and a pigment that absorbs lights in other wavelength ranges than a particular wavelength range. The color filter layers CFL1, CFL2 and CFL3 may be disposed in the sub-pixels SPXn, respectively, to transmit only some of the lights incident on the color filter layers CFL1, CFL2 and CFL3 in the respective sub-pixels SPXn. The sub-pixels SPXn of the display device 1 may selectively display only the lights transmitted through the color filter layers CFL1, CFL2 and CFL3. According to an embodiment of the disclosure, the first color filter layer CFL1 may be a red R color filter layer, the second color filter layer CFL2 may be a green G color filter layer, and the third color filter layer CFL3 may be a blue B color filter layer. The light emitted from the light-emitting diodes ED may pass through the color control structures TPL, WCL1 and WCL2 to exit through the color filter layers CFL1, CFL2 and CFL3.

The color patterns CP1, CP2 and CP3 may be disposed on the first overcoat layer OC1 or the color filter layers CFL1, CFL2 and CFL3. The color patterns CP1, CP2 and CP3 may include the same material as the color filter layers CFL1, CFL2 and CFL3 and may be disposed in the blocking area BA. In the light-blocking area BA, the color patterns CP1, CP2 and CP3 and the different color filter layers CFL1, CFL2 and CFL3 are disposed such that they are stacked on one another, and transmission of light can be blocked in the region where they are stacked on one another.

The first color pattern CP1 may include the same material as that of the first color filter layer CFL1 and may be disposed in the light-blocking area BA. The first color pattern CP1 may be disposed directly on the first overcoat layer OC1 in the light-blocking area BA but may not be disposed in the light-blocking area BA adjacent to the first wavelength control area LA1 of the first sub-pixel SPX1. The first color pattern CP1 may be disposed in the light-blocking area BA between the second sub-pixel SPX2 and the third sub-pixel SPX3. The first color filter layer CFL1 may be disposed in the light-blocking area BA around the first sub-pixel SPX1.

The second color pattern CP2 may include the same material as that of the second color filter layer CFL2 and may be disposed in the light-blocking area BA. The second color pattern CP2 may be disposed directly on the first overcoat layer OC1 in the light-blocking area BA but may not be disposed in the light-blocking area BA adjacent to the second wavelength control area LA2 of the second sub-pixel SPX2. The second color pattern CP2 may be disposed in the light-blocking area BA between the first sub-pixel SPX1 and the third sub-pixel SPX3, or at the boundary between the outermost sub-pixel SPXn of the display area DA and the non-display area NDA. The second color filter layer CFL2 may be disposed in the light-blocking area BA around the second sub-pixel SPX2.

Similarly, the third color pattern CP3 may include the same material as that of the third color filter layer CFL3 and may be disposed in the light-blocking area BA. The third color pattern CP3 may be disposed directly on the first overcoat layer OC1 in the light-blocking area BA but may not be disposed in the light-blocking area BA adjacent to the third wavelength control area LA3 of the third sub-pixel SPX3. The third color pattern CP3 may be disposed in the light-blocking area BA between the first sub-pixel SPX1 and the second sub-pixel SPX2. The third color filter CFL3 may be disposed in the light-blocking area BA around the third sub-pixel SPX3.

In the display device 1, the region where the bank layer BNL and the upper bank layer UBN overlap each other may be the light-blocking area BA. In the light-blocking area BA, each of the first color pattern CP1, the second color pattern CP2 and the third color pattern CP3 may be disposed to overlap at least one of the color filter layers CFL1, CFL2, and CFL3 including different color materials. For example, the first color pattern CP1 may be disposed to overlap the second color filter layer CFL2 and the third color filter layer CFL3, the second color pattern CP2 may be disposed to overlap the first color filter layer CFL1 and the third color filter layer CFL3, and the third color pattern CP3 may be disposed to overlap the first color filter layer CFL1 and the second color filter layer CFL2. In each of the light-blocking areas BA, the color patterns CP1, CP2 and CP3 having different colorants and the different color filter layers CFL1, CFL2 and CFL3 may overlap each other, so that transmission of light can be blocked.

The color patterns CP1, CP2 and CP3 may be stacked on the color filter layers CFL1, CFL2 and CFL3, and color mixing between adjacent areas can be prevented by the materials including different colorants.

The second overcoat layer OC2 may be disposed on the color filter layers CFL1, CFL2 and CFL3 and the color patterns CP1, CP2 and CP3. The second overcoat layer OC2 may be disposed throughout the entire display area DA, and may be partially disposed in the non-display area NDA. The second overcoat layer OC2 may include an organic insulating material to protect the elements disposed in the display area DA from the outside. The upper surface of the second overcoat layer OC2 may be the upper surface of the display panel 300.

The film member 100 may be disposed on the second overcoat layer OC2. Specifically, an adhesive layer ADH may be interposed between the film member 100 and the second overcoat layer OC2 so that the second overcoat layer OC2 and the film member 100 can be adhered to each other.

The film member 100 can protect the upper surface of the display device 1 as described above. The film member 100 may include an anti-fingerprint film 110 disposed at the top and a base film 130.

The anti-fingerprint film 110 of the film member 100 can prevent a user's fingerprint left on the display device 1. An appropriate structure of the anti-fingerprint film 110 may be employed.

The base film 130 of the film member 100 may work as the base of the film member 100. The base film 130 may include a material having a certain degree of rigidity. In some embodiments, the base film 130 may include, but is not limited to, triacetyl cellulose (TAC). As described above, the base film 130 has a certain degree of rigidity, so that it can protect the exterior of the display device 1.

As described above, the chassis member 500 may support the bottom of the display panel 300 to increase mechanical strength. The chassis member 500 may be disposed on the bottom of the display panel 300, i.e., the bottom of the substrate SUB of the display panel 300.

A heat dissipation layer GP may be disposed between the chassis member 500 and the display panel 300. The heat dissipation layer GP can block electromagnetic waves output from the display panel 300. In some embodiments, the heat dissipation layer GP may include, but is not limited to, graphite. Hereinafter, display devices according to other embodiments of the disclosure will be described.

In the following description, the same or similar elements will be denoted by the same or similar reference numerals, and redundant descriptions will be omitted or briefly described.

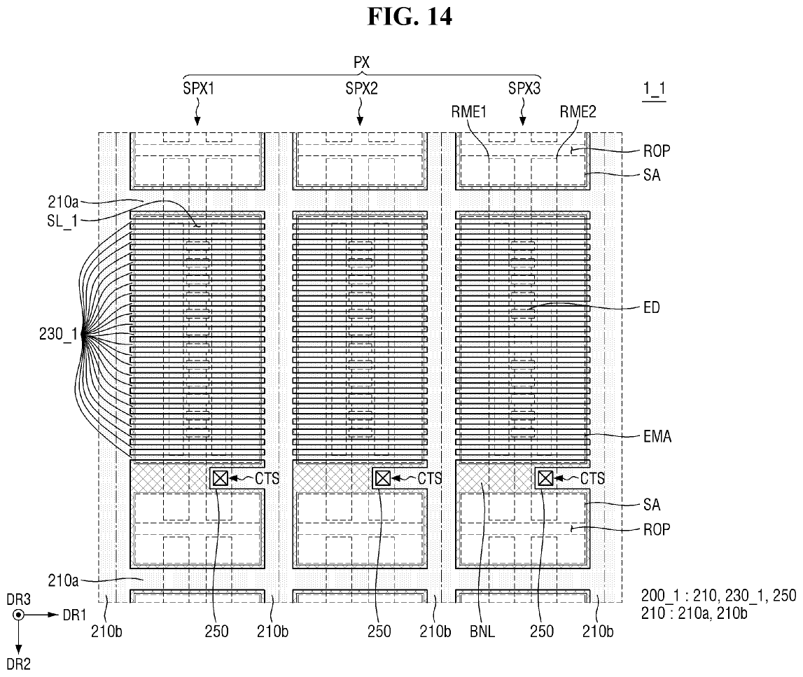

FIG. 14 is a plan view schematically showing an electrode pattern layer of a display device according to another embodiment of the disclosure.

In a display device 1_1 according to an embodiment of FIG. 14, slits SL_1 formed by a slit pattern 230_1 of an electrode pattern layer 200_1 may be extended in the first direction DR1. In other words, the extending direction of the slit pattern 230_1 may be substantially identical to the extending direction of the light-emitting elements ED.

According to this embodiment, slit patterns 230_1 may be disposed such that they may be extended in the first direction DR1 and may be spaced apart from one another in the second direction DR2. Accordingly, in case that the emission area EMA has a rectangular shape including longer sides in the second direction DR2 and shorter sides in the first direction DR1, the number of slits SL_1 can be increased, so that light output from the light-emitting elements ED can be more readily scattered.

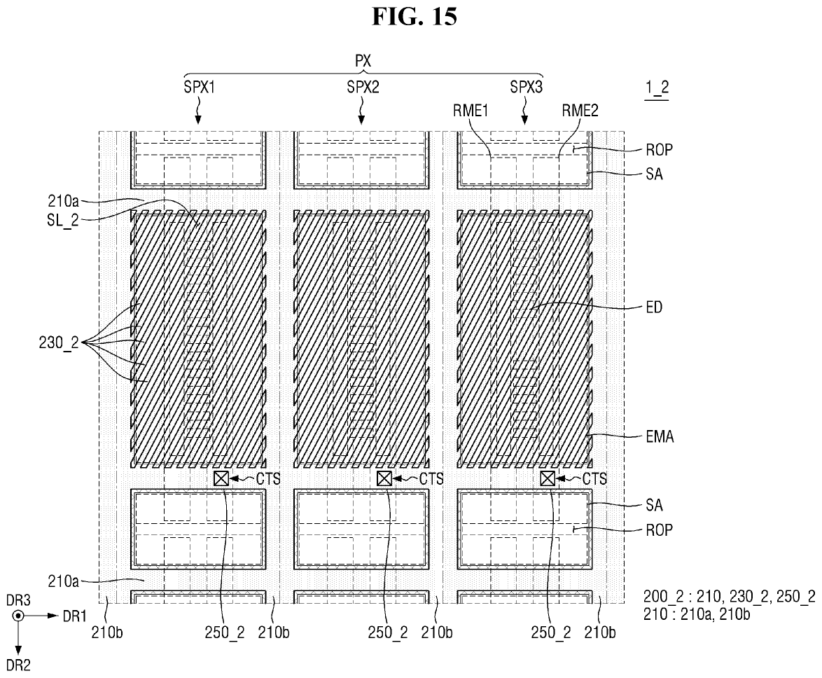

FIG. 15 is a plan view schematically showing an electrode pattern layer of a display device according to yet another embodiment of the disclosure.

In a display device 1_2 according to an embodiment of FIG. 15, slits SL_2 formed by slit patterns 230_2 of an electrode pattern layer 200_2 may be extended in a diagonal direction with respect to the emission area EMA. For example, the extending direction of the slits SL_2 may be a direction between the first direction DR1 and the opposite direction to the second direction DR2.

According to this embodiment, a ground contact 250_2 may be extended in the first direction DR1 such that it traverses between one side of the emission area EMA in the second direction DR2 and the opposite side of the subsidiary area SA in the second direction DR2 that is disposed on the one side of the emission area in the second direction DR2, may connect between two adjacent second ground portions 210b, and may be formed integrally with the ends of the slit pattern 230_2 that are extended to one side of the emission area EMA in the second direction DR2 among the slit patterns 230_2. Accordingly, the ends of the slit pattern 230_2 extended from the one side of the emission area EMA in the first direction DR1 to the one side in the second direction DR2 can be stably fixed. As a result, the mechanical stability of the slit pattern 230_2 can be improved.

According to this embodiment, as the extending direction of the slits SL_2 obliquely crosses the extending direction of the light-emitting elements ED, the number of the slits SL_2 can be increased, and the light output from the light-emitting elements ED can be scattered more effectively.

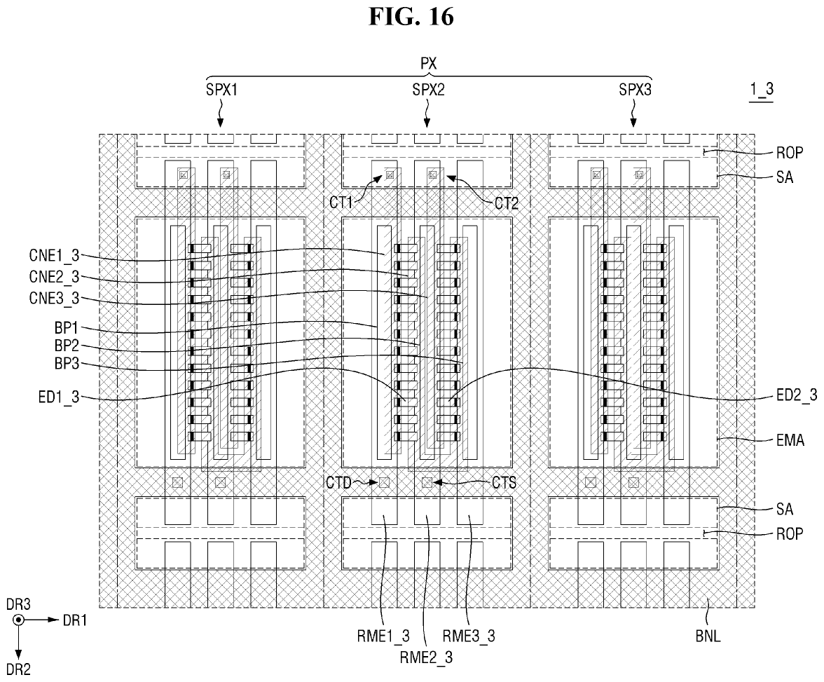

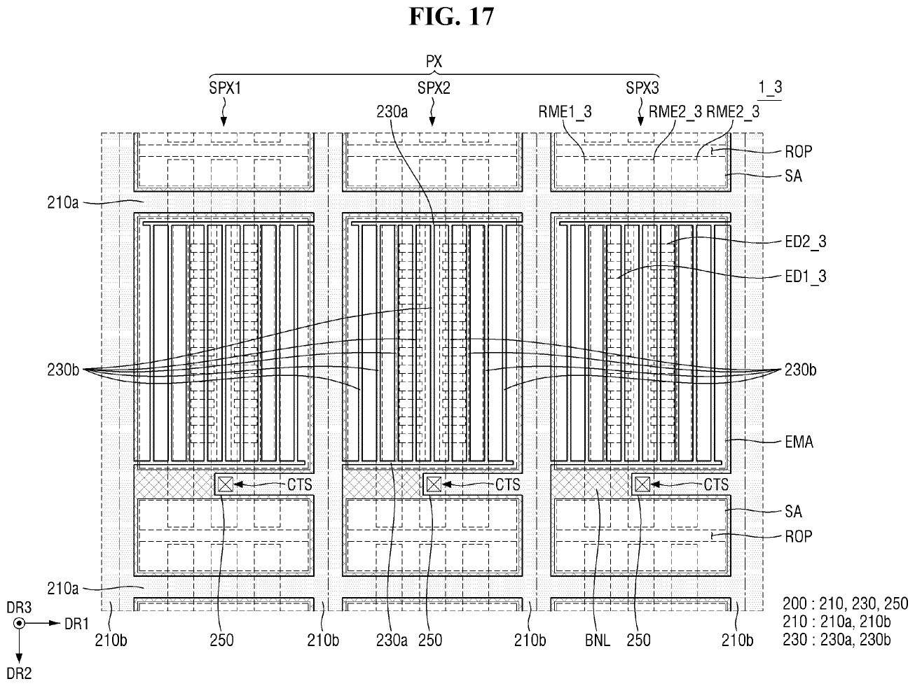

FIG. 16 is a plan view schematically showing light-emitting elements, alignment electrodes and connection electrodes of a display device according to still another embodiment of the disclosure. FIG. 17 is a plan view schematically showing an electrode pattern layer of the display device according to an embodiment of FIG. 16.

Referring to FIGS. 16 and 17, in a display device 1_3 according to this embodiment, the light-emitting elements ED may be arranged in columns, and the light-emitting elements ED may be connected in series in each of the columns. In some embodiments, the light-emitting elements ED may be arranged in, but are not limited to, two columns. For example, the light-emitting elements ED may be arranged in three or more columns, and the light-emitting elements ED may be connected in series in each of the columns. In the example shown in FIGS. 16 and 17, the light-emitting elements ED are arranged in two columns. In the following description, it is assumed that the light-emitting elements ED are arranged in two columns for convenience of illustration. The display device 1_3 according to this embodiment may further include a third alignment electrode RME3_3, a third connection electrode CNE3_3, and a third bank pattern BP3.

The third bank pattern BP3 may be disposed on one side of the second bank pattern BP2 in the first direction DR1. The third alignment electrode RME3_3 may be disposed on the third bank pattern BP3.

The first alignment electrode RME1_3 according to this embodiment may be substantially identical to the first alignment electrode RME1 of the display device 1 according to an embodiment of FIG. 5, and the second alignment electrode RME2_3 according to this embodiment may be substantially identical to the second alignment electrode RME2 of the display device 1 according to an embodiment of FIG. 5; and, therefore, redundant descriptions will be omitted.

The third alignment electrode RME3_3 may be disposed on one side of the second alignment electrode RME2_3 in the first direction DR1, and may be extended in the second direction DR2 to the subsidiary area SA beyond the emission area EMA. The third alignment electrode RME3_3 of one sub-pixel SPXn may be separated from the third alignment electrode RME3_3 of the neighboring sub-pixel SPXn at the separation region ROP.

Multiple first light-emitting elements ED1_3 may be arranged in the second direction DR2 between the first alignment electrode RME1_3 and the second alignment electrode RME2_3, and multiple second light-emitting elements ED2_3 may be arranged in the second direction DR2 between the second alignment electrode RME2_3 and the third alignment electrode RME2_3.

The orientation of the first light-emitting elements ED1_3 and the orientation of the second light-emitting elements ED2_3 may be reversed. For convenience of illustration, an end of each of the first light-emitting elements ED1_3 and the second light-emitting elements ED2_3 that may be adjacent to the second semiconductor layer 32 is referred to as a first end, while another end that may be adjacent to the first semiconductor layer 31 (see FIG. 6) is referred to as a second end. The first end of each of the first light-emitting elements ED1_3 may be disposed on the first alignment electrode RME1_3, the second end may be disposed on the second alignment electrode RME2_3, the second end of each of the second light-emitting elements ED2_3 may be disposed on the second alignment electrode RME2_3, and the first end may be disposed on the third alignment electrode RME3_3.

In the display device 1_3 according to this embodiment, a first connection electrode CNE1_3 may be disposed on the first alignment electrode RME1_3 to be in contact with the first end of each of the first light-emitting elements ED1_3 and may be electrically connected to the first alignment electrode RME1_3 via the first contact CT1.

The second connection electrode CNE2_3 may be disposed on the second alignment electrode RME2_3 and the third alignment electrode RME3_3. A part of the second connection electrode CNE2_3 may be in contact with the second end of each of the first light-emitting elements ED1_3, and another part may be in contact with the first end of each of the second light-emitting elements ED2_3. The second connection electrode CNE2_3 may have a curved shape at least once.

The third connection electrode CNE3_3 may be disposed on the second alignment electrode RME2_3 to be in contact with the second end of each of the second light-emitting elements ED2_3. The third connection electrode CNE3_3 may be electrically connected to the second alignment electrode RME2_3 through the second contact CT2.

Due to the connection relationship between the light-emitting elements ED1_3 and ED2_3 as described above, even if one light-emitting element is electrically connected to electrodes other than the connection electrodes CNE1_3, CNE2_3 and CNE3_3 and does not emit light, other light-emitting elements can emit light. For example, if one of the first light-emitting elements ED1_3 is electrically connected to an electrode other than the connection electrodes CNE1_3, CNE2_3 and CNE3_3, a connection failure occurs. As a result, all of the first light-emitting elements ED1_3 arranged in the second direction DR2 may fail to emit light. In such case, the second light-emitting elements ED2_3 can emit light regardless of the connection failure of the first light-emitting elements ED1_3. Accordingly, it may be necessary to scatter light output from the second light-emitting elements ED2_3 to compensate for the light efficiency that is lowered because the first light-emitting elements ED1_3 do not emit light.

For this reason, as shown in FIG. 17, it may be possible to scatter light output from the light-emitting elements ED1_3 and ED2_3 by disposing the electrode pattern layer 200. FIG. 17 shows that the electrode pattern layer 200 according to an embodiment of FIG. 7 is disposed, but the disclosure is not limited thereto. For example, the electrode pattern layer 200_1 according to an embodiment of FIG. 14 or the electrode pattern layer 200_2 according to an embodiment of FIG. 15 may also be applied.

In concluding the detailed description, those skilled in the art will appreciate that many variations and modifications can be made to the embodiments without substantially departing from the principles of the disclosure. Therefore, the embodiments of the disclosure are used in a generic and descriptive sense only and not for purposes of limitation.

What is claimed is:

1. A display device comprising:
a bank layer defining an emission area in which light-emitting elements are disposed;
a first electrode and a second electrode that are spaced apart from each other in the emission area, the light-emitting elements being disposed between the first electrode and the second electrode; and
an electrode pattern layer disposed above the bank layer, the light-emitting elements, the first electrode and the second electrode,
wherein the electrode pattern layer includes:
a lattice pattern that does not overlap the emission area and that surrounds edges of the emission area; and
a slit pattern overlapping the emission area.

2. The display device of claim 1, wherein
the lattice pattern overlaps the bank layer, and
the slit pattern does not overlap the bank layer.

3. The display device of claim 2, wherein
a first supply voltage is applied to the first electrode,
a second supply voltage having a lower level than a level of the first supply voltage is applied to the second electrode, and
the electrode pattern layer further comprises a contact electrically connected to the second electrode.

4. The display device of claim 3, wherein the second electrode is in direct contact with the contact of the electrode pattern layer.

5. The display device of claim 1, wherein
the slit pattern comprises a plurality of scattering members spaced apart from one another with slits extended to traverse the emission area therebetween, and
at least one of the plurality of scattering members overlaps the light-emitting elements.

6. The display device of claim 5, further comprising:
a capping layer disposed between the light-emitting elements and the plurality of scattering members; and
a wavelength conversion material disposed on an upper surface of the plurality of scattering members to convert a wavelength of light output from the light-emitting elements.

7. The display device of claim 6, wherein the scattering members and the lattice pattern comprise a same material.

8. The display device of claim 7, wherein the scattering members comprise a transparent conductive oxide.

9. The display device of claim 6, wherein the slits are extended in a direction parallel to an extending direction of the light-emitting elements.

10. The display device of claim 6, wherein the slits are extended in a direction intersecting an extending direction of the light-emitting elements.

11. A display device comprising:
a first electrode disposed on a substrate to receive a first supply voltage;
a second electrode spaced apart from the first electrode on the substrate to receive a second supply voltage having a level lower than a level of the first supply voltage;
light-emitting elements disposed on a space between the first electrode and the second electrode;
a capping layer disposed above the first electrode, the second electrode, and the light-emitting elements; and
a ground electrode disposed on the capping layer,
wherein the ground electrode is electrically connected to the second electrode.

12. The display device of claim 11, further comprising:
a second supply voltage line disposed between the substrate and the second electrode and applying the second supply voltage to the second electrode; and
a driver disposed on the substrate to apply a driving signal to the light-emitting elements,
wherein the second supply voltage line and the driver are electrically connected with each other.

13. The display device of claim 12, further comprising:
a via insulating layer disposed between the second supply voltage line and the second electrode,
wherein the second electrode is in electrical contact with the second supply voltage line through an electrode contact hole penetrating the via insulating layer.

14. The display device of claim 13, wherein
the electrode contact hole passes through the capping layer, and
the ground electrode is in direct contact with the second electrode through the electrode contact hole.

15. The display device of claim 14, wherein the ground electrode does not overlap the light-emitting elements.

16. The display device of claim 12, further comprising:
a plurality of scattering members spaced apart from one another, at least one of the scattering members overlapping the light-emitting elements,
wherein the ground electrode and the plurality of scattering members comprise a same material.

17. The display device of claim 16, wherein the ground electrode comprises a transparent conductive oxide.

18. A display device comprising:
a bank layer disposed on a substrate to define an emission area in which light-emitting elements are disposed;
a first electrode and a second electrode that are disposed on the substrate and spaced apart from each other in the emission area, the light-emitting elements disposed between the first electrode and the second electrode;
a capping layer disposed above the bank layer, the first electrode, the second electrode, and the light-emitting elements; and
a plurality of scattering members disposed on the capping layer such that the plurality of scattering members are spaced apart from one another,
wherein at least one scattering member among the plurality of scattering members overlaps the light-emitting elements.

19. The display device of claim 18, wherein the plurality of scattering members do not overlap the bank layer.

20. The display device of claim 19, wherein the plurality of scattering members comprise a transparent conductive oxide.
